(19) United States
(12) Patent Application Publication
(10) Pub. No.: US 2010/0297846 A1
(43) Pub. Date: Nov. 25, 2010

(54) Method of manufacturing a semiconductor device and substrate processing apparatus

(75) Inventors: Yukinao Kaga, Toyama-shi (JP); Tatsuyuki Saito, Toyama-shi (JP); Masanori Sakai, Takaoka-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/801,082

(22) Filed: May 20, 2010

(30) Foreign Application Priority Data
May 25, 2009 (JP) JP2009-125113
May 19, 2010 (JP) JP2010-115612

(51) Int. Cl. H01L 21/285; C23C 16/06; C23C 16/34

(52) U.S. Cl. 438/680; 118/715; 257/E21.17

(57) ABSTRACT

A method of manufacturing a semiconductor device includes the steps of: forming a first metal film on the substrate placed in a processing chamber by alternately supplying at least one type of a metal compound that is an inorganic raw material and a reactant gas that has reactivity to the metal compound to the processing chamber more than once; forming a second metal film on the substrate by simultaneously supplying at least one type of a metal compound that is an inorganic raw material and a reactant gas that has reactivity to the metal compound to the processing chamber once so that the metal compound and the reactant gas are mixed with each other; and modifying at least one of the first metal film and the second metal film is modified using at least one of the reactant gas and an inert gas after at least one of the alternate supply process and the simultaneous supply process. It thus becomes possible to provide a dense, low-resistive metal film having a smooth film surface with a better quality in comparison with a titanium nitride film formed by the CVD method at a higher deposition rate, that is, at a higher productivity, in comparison with a titanium nitride film formed by the ALD method at a low temperature.

### BACKGROUND OF THE INVENTION

1. Field of the Invention

The present invention relates to a method of manufacturing a semiconductor device and a substrate processing apparatus, and more particularly, to a method of manufacturing a semiconductor device including a process by which a metal film is formed on a substrate (wafer) and a substrate processing apparatus that forms a metal film on a substrate.

2. Description of the Related Art

There is the CVD (Chemical Vapor Deposition) method as one technique of forming a predetermined film on a substrate. The CVD method is a method of forming a film made up of elements contained in raw material molecules on a substrate by utilizing a reaction of at least two types of raw materials in a gas phase or on the substrate surface. Also, there is the ALD (Atomic Layer Deposition) method as one type of the CVD method. The ALD method is a method of forming a film by supplying raw materials, which are at least two types of raw materials used for film formation, onto a substrate alternately one at a time under specific film formation conditions (temperature, time, and so forth) for letting the raw materials be adsorbed on an atomic layer-by-atomic layer basis, so that the film formation is controlled at an atomic layer level by utilizing a surface reaction. In comparison with the CVD method in the related art, a processing can be applied at a lower substrate temperature (processing temperature) and the thickness of a film to be formed can be controlled with the number of film formation cycles. In a case where an organic raw material is used as the raw material, methyl groups remain and the resistance value varies. In a case where TDMAT (tetrakis(dimethylamino)titanium) is used as an organic raw material, TDMAT undergoes self-decomposition to form a film at a low-temperature point, such as at a throat portion of a vertical apparatus, due to its self-decomposition temperature as low as 150° C. The film eventually comes off and produces particles.

Examples of a metal film formed on the substrate include a titanium nitride film (TiN) as is described, for example, in WO2007/020874.

A continuous film of a titanium nitride film generally shows a prism-like structure. In a case where a titanium nitride film is formed by the CVD method, however, the film tends to grow randomly from the beginning to the end of film formation. Consequently, crystal grains may become bulky or the film surface may become rough in comparison with a case where it is formed by the ALD method. An increase of the proportion of voids in the film makes the film less dense, which causes the resistivity to be increased.

In particular, in a case where the processing temperature is dropped as low as 300° C., a thorny film is grown and the surface roughness and the film density are deteriorated considerably.

Meanwhile, a continuous film of a titanium nitride film formed by the ALD method has a smooth surface and a relatively low resistance value in comparison with a case where it is formed by the CVD method. In addition, a satisfactory step coverage can be obtained. However, because a deposition rate is slow in comparison with a case where the CVD method is used, it takes a time to obtain a desired film thickness. A thermal budget of the substrate is thus increased noticeably.

### SUMMARY OF THE INVENTION

An object of the invention is to provide a method of manufacturing a semiconductor device and a substrate processing apparatus that solve the problems discussed above and thereby form a dense, low-resistive metal film having a smooth film surface at a high deposition rate and a low temperature.

A method of manufacturing a semiconductor device according to an aspect of the invention includes the steps of carrying out an alternate supply process by which a first metal film is formed on a substrate placed in a processing chamber by alternately supplying at least one type of a metal compound that is an inorganic raw material and a reactant gas that has reactivity to the metal compound to the processing chamber more than once, carrying out a simultaneous supply process by which a second metal film is formed on the substrate placed in the processing chamber by simultaneously supplying at least one type of a metal compound that is an inorganic raw material and a reactant gas that has reactivity to the metal compound to the processing chamber once so that the metal compound and the reactant gas are mixed with each other, and carrying out a modification process by which at least one of the first metal film and the second metal film is modified using at least one of the reactant gas and an inert gas after at least one of the alternate supply process and the simultaneous supply process.

A method of manufacturing a semiconductor device according to another aspect of the invention includes the steps of carrying out an alternate supply process by which a first metal film is formed on a substrate placed in a processing chamber by alternately supplying at least one type of a metal compound and a reactant gas that has reactivity to the metal compound to the processing chamber more than once, and carrying out a simultaneous supply process by which a second metal film is formed on the substrate by simultaneously supplying at least one type of a metal compound and a reactant gas that has reactivity to the metal compound to the processing chamber so that the metal compound and the reactant gas are mixed with each other. In the simultaneous supply process, a supply of the metal compound and the reactant gas is stopped to remove an atmosphere in the processing chamber after the metal compound and the reactant gas are supplied simultaneously to the processing chamber so that the metal compound and the reactant gas are mixed with each other, after which the reactant gas is supplied to the processing chamber and an atmosphere in the processing chamber is subsequently removed by stopping a supply of the reactant gas.

A method of manufacturing a semiconductor device according to still another aspect of the invention includes the steps of carrying out an alternate supply process by which a first metal film is formed on a substrate placed in a processing chamber by alternately supplying a metal compound that is an inorganic raw material and a reactant gas that has reactivity to the metal compound to the processing chamber more than once, and carrying out a simultaneous supply process by which a second metal film is formed on the substrate placed in the processing chamber by supplying at least one type of a metal compound that is an inorganic raw material and a reactant gas that has reactivity to the metal compound to the processing chamber so that the metal compound and the reactant gas are mixed with each other. In the alternate supply process, the first metal film is a laminated film of a third metal film and a fourth metal film formed by carrying out, a predetermined number of times, a process by which the third metal film is formed on the substrate by alternately supplying a first metal compound and the reactant gas to the processing chamber more than once and a process by which the fourth metal film is formed on the substrate by alternately supplying a second metal compound that is different from the first metal compound and the reactant gas to the processing chamber more than once.

A method of manufacturing a semiconductor device according to still another aspect of the invention includes the steps of carrying out an alternate supply process by which a first metal film is formed on a substrate placed in a processing chamber by alternately supplying at least one type of a metal compound that is an inorganic raw material and a reactant gas that has reactivity to the metal compound to the processing chamber more than once, and carrying out a simultaneous supply process by which a second metal film is formed on the substrate placed in the processing chamber by simultaneously supplying at least one type of a metal compound that is an inorganic raw material and a reactant gas that has reactivity to the metal compound to the processing chamber once so that the metal compound and the reactant gas are mixed with each other.

A substrate processing apparatus according to still another aspect of the invention includes a processing chamber that accommodates a substrate, a metal compound supply system that supplies at least one type of a metal compound that is an inorganic raw material to the processing chamber, a reactant gas supply system that supplies a reactant gas that has reactivity to the metal compound to the processing chamber, an exhaust system that exhausts an atmosphere in the processing chamber, and a control portion that controls the metal compound supply system, the reactant gas supply system, and the exhaust system. The control portion carries out an alternate supply process by which a first metal film is formed on the substrate by alternately supplying the metal compound and the reactant gas to the processing chamber more than once and a simultaneous supply process by which a second metal film is formed on the substrate by simultaneously supplying the metal compound and the reactant gas to the processing chamber once so that the metal compound and the reactant gas are mixed with each other, by controlling the metal compound supply system, the reactant gas supply system, and the exhaust system, so that a predetermined metal film is formed on the substrate.

According to the invention, it becomes possible to provide a titanium nitride film having a better quality in comparison with a titanium nitride film formed by the CVD method at a higher deposition rate, that is, at a higher productivity, in comparison with a titanium nitride film formed by the ALD method.

### BRIEF DESCRIPTION OF THE DRAWINGS

FIG. 1 is a diagonal perspective view schematically showing the configuration of a substrate processing apparatus suitably used in one embodiment of the invention;

FIG. 2 is a view schematically showing the configuration of an example of a processing furnace and accompanying members suitably used in one embodiment of the invention and particularly showing a processing furnace portion in longitudinal section;

FIG. 3 is a cross section of the processing furnace shown in FIG. 2 suitably used in one embodiment of the invention taken on line A-A;

FIG. 4 is a view showing a control flow in a first embodiment of the invention;

FIG. 5 is a view showing a film formation sequence of a titanium nitride film in a first film formation process in the first embodiment of the invention;

FIG. 6 is a view showing a film formation sequence of a titanium nitride film in a second film formation process in the first embodiment of the invention;

FIG. 7 is a view showing a control flow in another embodiment of the invention;

FIG. 8 is a view showing a control flow in still another embodiment of the invention;

FIG. 9 is a view showing a control flow in still another embodiment of the invention;

FIG. 10 is a view showing a control flow in still another embodiment of the invention;

FIG. 11A is a view showing a case where a film is formed of a single CVD layer and FIG. 11B is a view showing a case where a film is formed of an ALD layer and a CVD layer deposited continuously for comparison of a surface morphology;

FIG. 12 is a view schematically showing the configuration of an example of a processing furnace and accompanying members suitably used in a second embodiment of the invention and particularly showing a processing furnace portion in longitudinal section;

FIG. 13 is a cross section of the processing furnace shown in FIG. 12 suitably used in the second embodiment of the invention taken on line A-A;

FIG. 14 is a view showing a control flow in the second embodiment of the invention;

FIG. 15 is a view showing a film formation sequence in a first film formation process in the second embodiment of the invention;

FIG. 16 is a view showing a control flow in a third embodiment of the invention;

FIG. 17 is a view showing a film formation sequence in a second film formation process in the third embodiment of the invention; and

FIG. 18 is a transverse cross section of a processing furnace in a fourth embodiment of the invention.

### DESCRIPTION OF THE PREFERRED EMBODIMENTS

Hereinafter, preferred embodiments of the invention will be described with reference to the drawings.

A substrate processing apparatus according to one embodiment is formed as an example of a semiconductor manufacturing apparatus used to fabricate semiconductor devices (ICs (Integrated Circuits)). The following will describe a case where a vertical apparatus that applies processing, such as a film formation processing, to a substrate as an example of the substrate processing apparatus. It should be appreciated, however, that the invention is not based on the premise of using a vertical apparatus and, for example, a sheet-fed apparatus can be used as well.

### Overall Configuration of Apparatus

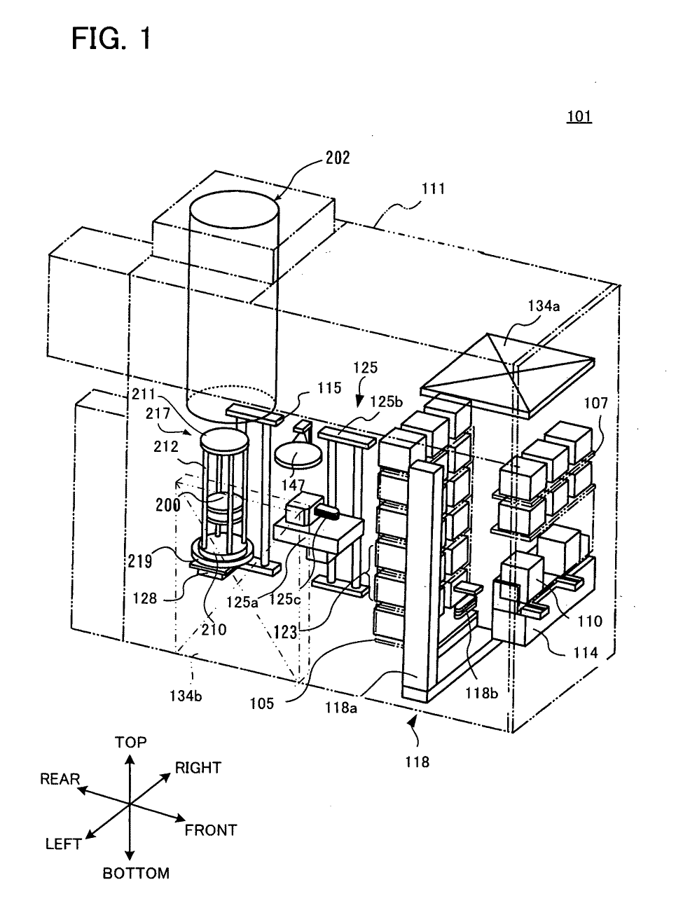

As is shown in FIG. 1, a substrate processing apparatus 101 uses cassettes 110 that accommodate wafers 200 as an example of a substrate in each. The wafers 200 are made of materials, such as silicon. The substrate processing apparatus 101 includes a housing 111 and a cassette stage 114 is provided inside the housing 111. The cassettes 110 are carried in onto the cassette stage 114 and carried out from the top of the cassette stage 114 by an in-process carrier device (not shown).

On the cassette stage 114, the cassettes 110 are mounted by the in-process carrier device in such a manner that the wafers 200 accommodated therein maintain a vertical posture and the wafer ports of the cassettes 110 face upward. The cassette stage 114 is configured operatively to rotate the cassettes 110 rearward of the housing 111 and clockwise by 90° in the longitudinal direction, so that the wafers 200 inside the cassettes 110 are in a horizontal posture and the wafer ports of the cassettes 110 face rearward of the housing 111.

A cassette shelf 105 is provided inside the housing 111 at substantially the center in the front-rear direction. The cassette shelf 105 is configured to store a plurality of the cassettes 110 in a plurality of rows and columns. The cassette shelf 105 is provided with a transfer shelf 123 that accommodates the cassettes 110 to be transported by a wafer transfer mechanism 125.

A spare cassette shelf 107 is provided above the cassette stage 114 and is configured to store extra cassettes 110.

A cassette transportation device 118 is provided between the cassette stage 114 and the cassette shelf 105. The cassette transportation device 118 is formed of a cassette elevator 118a capable of ascending and descending while holding the cassettes 110 and a cassette transportation mechanism 118b serving as a transportation mechanism. The cassette transportation device 118 is configured to transport the cassettes 110 between the cassette stage 114 and the cassette shelf 105 and between the cassette stage 114 and the spare cassette shelf 107 by continuous operations of the cassette elevator 118a and the cassette transportation mechanism 118b.

The wafer transfer mechanism 125 is provided behind the cassette shelf 105. The wafer transfer mechanism 125 is formed of a wafer transfer device 125a capable of rotating and linearly moving the wafer 200 in a horizontal direction and a wafer transfer device elevator 125b that moves the wafer transfer device 125a up and down. The wafer transfer device 125a is provided with tweezers 125c that pick up one wafer 200. The wafer transfer device 125 is configured to charge the wafer 200 into a boat 217 (charging) and to discharge the wafer 200 from the boat 217 (discharging) by using the tweezers 125c as a mounting portion of the wafer 200 by continuous operations of the wafer transfer device 125a and the wafer transfer device elevator 125b.

A processing furnace 202 in which to apply a heat processing to the wafers 200 is provided in the upper rear portion of the housing 111 and the processing furnace 202 is configured in such a manner that the lower end portion is opened and closed by a throat shutter 147.

A boat elevator 115 that moves the boat 217 up and down with respect to the processing furnace 202 is provided under the processing furnace 202. An arm 128 is linked to a ramp of the boat elevator 115 and a seal cap 219 is attached to the arm 128 in a horizontal posture. The seal cap 219 is configured not only to support the boat 217 vertically but also to block the lower end portion of the processing furnace 202.

The boat 217 includes a plurality of holding members and is configured to hold a plurality (for example, about 50 to 150) of the wafers 200 in a horizontal posture aligned with the centers lined up in a vertical direction.

A clean unit 134a that supplies a clean air, which is a purified atmosphere, is provided above the cassette shelf 105. The clean unit 134a is formed of a supply fan and a dust-proof filter and is configured to circulate a clean air within the housing 111.

A clean unit 134b that supplies a clear air is provided at the left end portion of the housing 111. The clean unit 134b is also formed of a supply fan and a dust-proof filter and is configured to circulate a clean air in the vicinity of the wafer transfer device 125a, the boat 217, and so forth. The clean air is exhausted to the outside of the housing 111 after it has circulated in the vicinity of the wafer transfer device 125a, the boat 217, and so forth.

### Operation of Processing Apparatus

A main operation of the substrate processing apparatus 101 will now be described.

When the cassette 110 is carried in onto the cassette stage 114 by the in-process transfer device (not shown), the cassette 110 is mounted in such a manner that the wafers 200 maintain a vertical posture on the cassette stage 114 and the wafer port of the cassette 110 faces upward. Subsequently, the cassette 110 is rotated rearward of the housing 111 and clockwise by 90° in the longitudinal direction by the cassette stage 114 so that the wafers 200 inside the cassette 110 are in a horizontal posture and the wafer port of the cassette 110 faces rearward of the housing 111.

Subsequently, the cassette 110 is automatically transported and delivered to a specified shelf position of the cassette shelf 105 or the spare cassette shelf 107 by the cassette transportation device 118 and after the cassette 110 is stored temporarily, it is transferred from the cassette shelf 105 or the spare cassette shelf 107 to the transfer shelf 123 by the cassette transportation device 118. Alternatively, the cassette 110 is directly transported to the transfer shelf 123 by the cassette transportation device 118.

When the cassette 110 is transferred onto the transfer shelf 123, one wafer 200 is picked up from the cassette 110 by the tweezers 125c of the wafer transfer device 125a through the wafer port and charged into the boat 217 (charging). The wafer transfer device 125a returns to the cassette 110 after it has delivered one wafer 200 to the boat 217 and charges the following wafer 200 into the boat 217.

When a preliminarily specified number of the wafers 200 are charged into the boat 217, the furnace shutter 147 that has been closing the lower end portion of the processing furnace 202 opens. The lower end portion of the processing furnace 202 is thus opened. Subsequently, the boat 217 holding a group of the wafers 200 is carried in the processing furnace 202 (loading) by an ascending operation of the boat elevator 115 and the bottom of the processing furnace 202 is blocked by the seal cap 219.

An arbitrary processing is applied to the wafers 200 in the processing furnace 202 after the loading. When the processing ends, the wafers 200 and the cassette 110 are carried out to the outside of the housing 111 by inversely carrying out the procedure described above.

Configuration of Processing Furnace

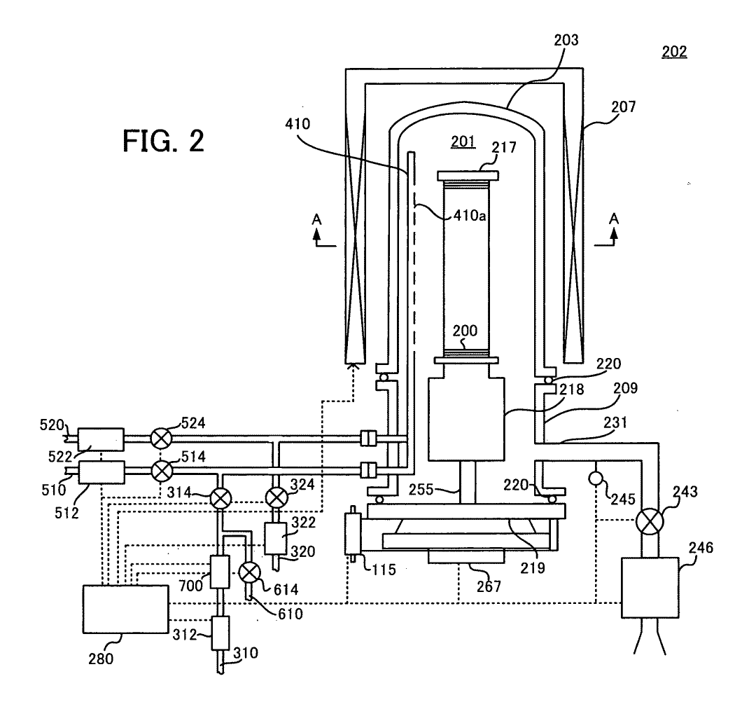

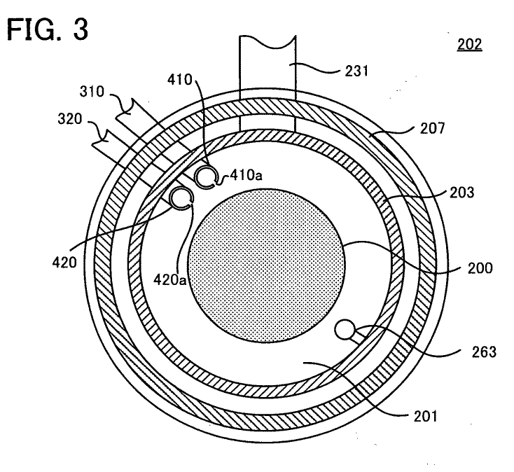

The processing furnace 202 applied to the substrate processing apparatus described above will now be described using FIG. 2 and FIG. 3.

As are shown in FIG. 2 and FIG. 3, the processing furnace 202 is provided with a heater 207, which is a heating device (heating unit, heating means) that heats the wafers 200. The heater 207 includes an insulation member in the shape of a top-closed cylinder and a plurality of heater wires and has a unit configuration in which the heater wires are provided to the insulation member. A reaction tube 203 made of quartz and used to apply a processing to the wafers 200 is provided on the inner side of the heater 207.

The seal cap 219 is provided under the reaction tube 203 as a throat lid capable of hermetically blocking the lower end opening of the reaction tube 203. The seal cap 219 is allowed to abut on the lower end of the reaction tube 203 from below in the vertical direction. The seal cap 219 is made of metal, for example, stainless, and formed in a disc shape. An O-ring 220 is provided on the top surface of the seal cap 219 as a seal member that abuts on the lower end of the reaction tube 203. A rotation mechanism 267 that rotates the boat 217 described below is provided to the seal cap 219 on the side opposite to a processing chamber 201. A rotation shaft 255 of the rotation mechanism 267 penetrates through the seal cap 219 to be connected to the boat 217 and is configured to rotate the wafers 200 by rotating the boat 217. The seal cap 219 is configured to be moved up and down in the vertical direction by the boat elevator 115 serving as the elevation mechanism provided to the outside of the reaction tube 203. This configuration makes it possible to carry the boat 217 in and out from the processing chamber 201.

The seal cap 219 is provided with a boat support base 218 that supports the boat 217. As is shown in FIG. 1, the boat 217 has a bottom plate 210 fixed to the boat support base 218 and a top plate 211 disposed above the bottom plate 210 and is configured in such a manner that a plurality of support columns 212 are bridged between the bottom plate 210 and the top plate 211. A plurality of the wafers 200 are held in the boat 217. A plurality of the wafers 200 are supported on the support columns 212 of the boat 217 while being maintained in a horizontal posture and regularly spaced apart from one another.

In the processing furnace 202 described above, the boat 217 that is being supported on the boat support base 218 is Inserted into the processing chamber 201 in a state where a plurality of the wafers 200 subject to batch processing are laminated in multiple stages in the boat 217 and the heater 207 heats the wafers 200 inserted into the processing chamber 201 to a predetermined temperature.

As are shown in FIG. 2 and FIG. 3, two gas supply pipings 310 and 320 (first gas supply piping 310 and second gas supply piping 320) that supply raw material gases are connected to the processing chamber 201.

The gas supply piping 310 is provided with, sequentially from the upstream end, a mass flow controller 312, which is as a flow rate control device (flow rate control means), a vaporizer 700, which is a vaporization unit (vaporization means), and a valve 314, which is an on-off valve. A nozzle 410 (first nozzle 410) is coupled to the tip end of the gas supply piping 310. The nozzle 410 extends in a top-bottom direction (loading direction of the wafers 200) along the inner wall of the reaction tube 203 in a circular space between the inner wall of the reaction tube 203 forming the processing chamber 201 and the wafers 200. A large number of gas supply holes 410a through which to supply a raw material gas are provided to the side surface of the nozzle 410. The gas supply holes 410a have opening areas provided from bottom to top in the same size or in progressively increasing sizes at the same opening pitch.

Further, the gas supply piping 310 is provided with a vent line 610 connected to an exhaust piping 231 described below and a valve 614 disposed between the vaporizer 700 and the valve 314. In a case where a raw material gas is not supplied to the processing chamber 201, the raw material gas is supplied to the vent line 610 via the valve 614. A first gas supply system (first gas supply unit, first gas supply means) is chiefly formed of the gas supply piping 310, the mass flow controller 312, the vaporizer 700, the valve 314, the nozzle 410, the vent line 610, and the valve 614.

A carrier gas supply piping 510 that supplies a carrier gas is connected to the gas supply piping 310. The carrier gas supply piping 510 is provided with a mass flow controller 512 and a valve 514. A first carrier gas supply system (first inert gas supply system, first inert gas supply unit, first inert gas supply means) is chiefly formed of the carrier gas supply piping 510, the mass flow controller 512, and the valve 514.

The gas supply piping 320 is provided with, sequentially from the upstream end, a mass flow controller 322, which is a flow rate control device (flow rate control means), and a valve 324. A nozzle 420 (second nozzle 420) is coupled to the tip end of the gas supply piping 320. As with the nozzle 410, the nozzle 420 extends in a top-bottom direction (the loading direction of the wafers 200) along the inner wall of the reaction tube 203 in a circular space between the inner wall of the reaction tube 203 forming the processing chamber 201 and the wafers 200. A large number of gas supply holes 420a through which to supply a raw material gas are provided to the side surface of the nozzle 420. As with the gas supply holes 410a, the gas supply holes 420a also have opening areas provided from bottom to top in the same size or in progressively increasing sizes at the same opening pitch. A second gas supply system (second gas supply unit, second gas supply means) is chiefly formed of the gas supply piping 320, the mass flow controller 322, the valve 324, and the nozzle 420.

Further, a carrier gas supply piping 520 that supplies a carrier gas is linked to the gas supply piping 320. The carrier gas supply piping 520 is provided with a mass flow controller 522 and a valve 524. A second carrier gas supply system (second inert gas supply system, second inert gas supply unit, second inert gas supply means) is chiefly formed of the carrier gas supply piping 520, the mass flow controller 522, and the valve 524.

For example, in a case where a raw material supplied from the gas supply piping 310 is a liquid, the raw material flowing from the gas supply piping 310 via the mass flow controller 312, the vaporizer 700, and the valve 314 merges with a carrier gas flowing in the carrier gas supply piping 510 and a reactant gas is supplied further into the processing chamber 201 via the nozzle 410. Also, for example, in a case where a raw material supplied from the gas supply piping 310 is a gas, the mass flow controller 312 is replaced with a mass flow controller for gas and the vaporizer 700 becomes unnecessary. Accordingly, the raw material flowing from the gas supply piping 320 via the mass flow controller 322 and the valve 324 merges with a carrier gas flowing in the carrier gas supply piping 520 and a reactant gas is supplied further into the processing chamber 201 via the nozzle 420.

As an example of the configuration described above, a Ti material (titanium tetrachloride (TiC1₄)), tetrakis(dimethylamino)titanium (TDMAT, Ti[N(CH₃)₂]₄), and tetrakis(diethylamino)titanium (TDEAT, Ti[N(CH₂CH₃)₂]₄) are introduced into the gas supply piping 310 as examples of the raw material gas. Ammonia (NH₃), nitrogen (N₂), nitrous oxide (N₂O), monomethyl hydrazine (CH₆N₂), which are nitriding materials, are introduced into the gas supply piping 320 as examples of a modifying raw material.

For example, a nitrogen (N₂) gas is supplied into the processing chamber 201 from the carrier gas supply pipings 510 and 520 via the mass flow controllers 512 and 522, the valves 514 and 524, and the gas supply pipings 510 and 520, and the nozzles 410 and 420, respectively.

For example, in a case where the gases described above are flown from the respective gas supply pipings, a raw material gas supply system, that is, a metal-containing gas (metal compound) supply system is formed of the first gas supply system. A reactant gas (modifying gas) supply system is formed of the second gas supply system.

The reaction tube 203 is provided with the exhaust piping 231 that exhausts an atmosphere in the processing chamber 201. A pressure sensor 245 serving as a pressure detector (pressure detection portion) that detects an internal pressure of the processing chamber 201 is connected to the exhaust piping 231. Also, a vacuum pump 246 serving as a vacuum exhauster is connected to the exhaust piping 231 via an APC (Auto Pressure Controller) valve 243 serving as a pressure adjustor (pressure adjustment portion). The reaction tube 203 is thus configured to be evacuated until the internal pressure of the processing chamber 201 reaches a predetermined pressure (degree of vacuum). The APC valve 243 is an on-off valve capable of evacuating the processing chamber 201 and stopping evacuation by opening and closing the valve and further capable of adjusting a pressure by regulating the valve opening degree. An exhaust system is chiefly formed of the exhaust piping 231, the APC valve 243, the vacuum pump 246, and the pressure sensor 245.

A temperature sensor 263 as a temperature detector is provided inside the reaction tube 203. The reaction tube 203 is configured in such a manner that the internal temperature of the processing chamber 201 becomes a desired temperature distribution by adjusting energization to the heater 207 according to the temperature information detected by the temperature sensor 263. The temperature sensor 263 is formed in the shape of a capital L as with the nozzles 410 and 420 and provided along the inner wall of the reaction tube 203.

The boat 217 is provided inside the reaction tube 203 at the center. The boat 217 is allowed to ascend and descend (enter into and exit from) with respect to the reaction tube 203 by the boat elevator 115. The boat rotation mechanism 267 that rotates the boat 217 to enhance homogeneity of the processing is provided to the lower end portion of the boat support base 218 that supports the boat 217. By driving the boat rotation mechanism 267, the boat 217 supported on the boat support base 218 is allowed to rotate.

The respective members described above including the mass flow controllers 312, 322, 512, and 522, the valves 314, 324, 514, and 524, the APC valve 243, the heater 207, the temperature sensor 263, the pressure sensor 245, the vacuum pump 246, the boat rotation mechanism 267, and the boat elevator 115, are connected to a controller 280. The controller 280 is an example of a control portion (control means) that controls an overall operation of the substrate processing apparatus 101 and configured to control flow rate adjustments by the mass flow controllers 312, 322, 512, and 522, opening and closing operations of the valves 314, 324, 514, and 524, a pressure adjustment operation according to the opening and closing of the APC valve 243 and the pressure sensor 245, a temperature adjustment operation of the heater 207 according the temperature sensor 263, start and stop of the vacuum pump 246, a rotation velocity adjustment of the boat rotation mechanism 267, and ascending and descending operations of the boat elevator 115.

### A Method of Manufacturing a Semiconductor Device

The following will describe an example of a method of forming an insulating film on a substrate when fabricating an LSI (Large Scale Integration) as one process in the fabrication sequence of a semiconductor device using the processing furnace 202 of the substrate processing apparatus described above. It should be appreciated that operations of the respective portions forming the substrate processing apparatus are controlled by the controller 280 in the following description.

### First Embodiment

This embodiment will describe a method of forming a titanium nitride film on a substrate as a metal film.

This method is divided to two processes so as to form titanium nitride films on the substrate by different film formation methods. Initially, a titanium nitride film is formed on the substrate by the ALD method as a first film formation process. Subsequently, a titanium nitride film is formed on the substrate by the CVD method as a second film formation process.

This embodiment will describe a case where TiCl₄ is used as a titanium (Ti)-containing raw material and NH₃ is used as a nitriding gas. Herein, a titanium-containing gas supply system (first element-containing gas supply system) is formed of the first gas supply system and a nitrogen-containing gas supply system (second element-containing gas supply system) is formed of the second gas supply system.

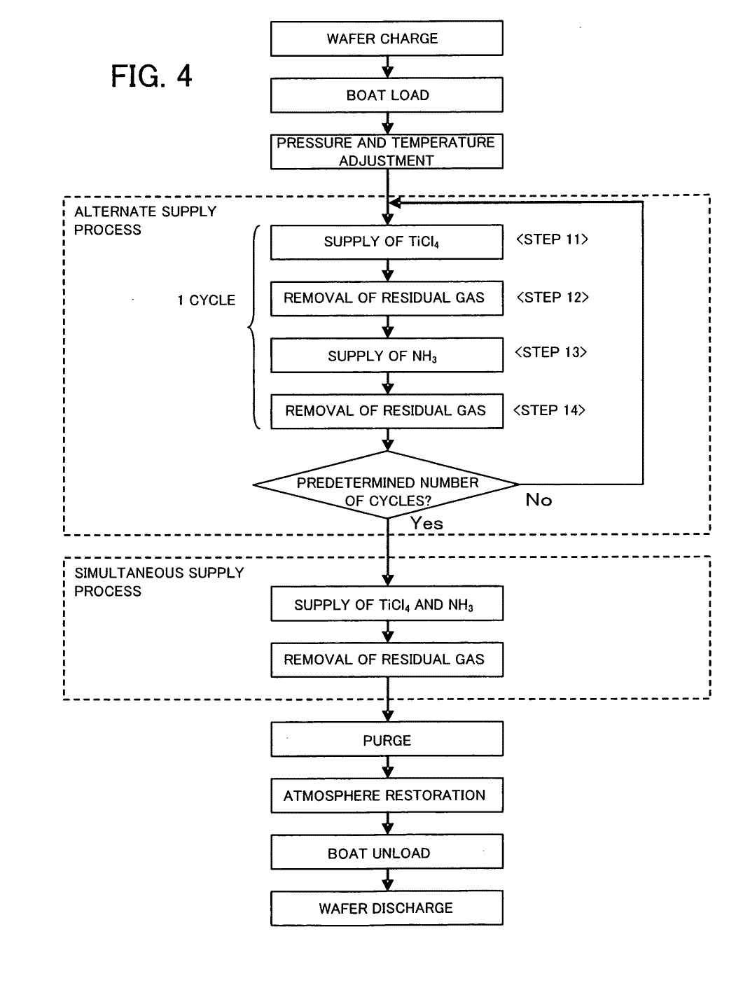

FIG. 4 shows an example of the control flow in this embodiment. Initially, when a plurality of the wafers 200 are charged into the boat 217 (wafer charge), the boat 217 supporting a plurality of the wafers 200 is lifted up by the boat elevator 115 and carried into the processing chamber 201 (boat loading). In this state, the seal cap 219 seals the lower end of the reaction tube 203 via the O-ring 220.

Further, in the film formation process, the controller 280 controls the substrate processing apparatus 101 as follows. That is, the controller 280 maintains the interior of the processing chamber 201 at a temperature in a range, for example, of 300° C. to 550° C., preferably at 450° C. or below, and more preferably at 450° C., by controlling the heater 207. Subsequently, a plurality of the wafers 200 are charged into the boat 217 and the boat 217 is carried into the processing chamber 201. Subsequently, the boat 217 is rotated by the boat drive mechanism 267 to rotate the wafers 200. Subsequently, the processing chamber 201 is vacuumed by actuating the vacuum pump 246 and by opening the APC valve 243. When the temperature of the wafers 200 becomes stable by reaching 450° C., the controller 280 carries out the processes described below while maintaining the internal temperature of the processing chamber 201 at 450° C.

### (1) First Film Formation Process (Alternate Supply Process)

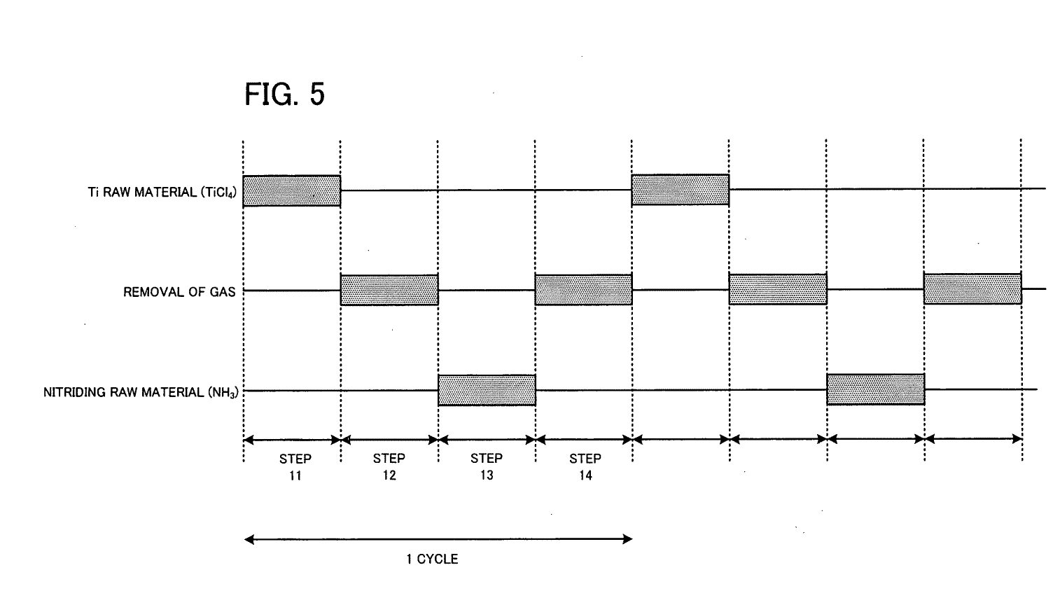

FIG. 5 shows a film formation sequence of a titanium nitride film in a first film formation process of this embodiment. In the first film formation process, a case where a film is formed on a substrate by the ALD method will be described. The ALD method is one type of the CVD method, and it is a method of forming a film by supplying raw material gases, which are at least two types of raw materials used for film formation, onto a substrate alternately one at a time under specific film formation conditions (temperature, time, and so forth) for letting the raw materials be adsorbed atom by atom on the substrate, so that a film is formed by utilizing a surface reaction. In this instance, the film thickness is controlled with the number of cycles of supplying the raw material gases (for example, given that the deposition rate is 1 Å/cycle, then 20 cycles are carried out to form a 20-Å-thick film).

### Step 11

In Step 11, TiCl₄ is flown. TiCl₄ is a liquid at normal temperature. In order to supply TiCl₄ to the processing chamber 201, there are a method of heating TiCl₄ to supply vaporized TiCl₄ and a method of using the vaporizer 700 while letting an inert gas called a carrier gas, such as He (helium), Ne (neon), Ar (argon), and N₂ (nitrogen), flow through a TiCl₄ container, so that vaporized part together with the carrier gas is supplied to the processing chamber 201. Herein, the latter case will be described by way of example.

TiCl₄ is flown to the gas supply piping 310 and a carrier gas (N₂) is flown to the carrier gas supply piping 510. The valve 314 of the gas supply piping 310, the valve 514 of the carrier gas supply piping 510, and the APC valve 243 of the exhaust piping 231 are opened all together. The carrier gas flows from the carrier gas supply piping 510 and a flow rate thereof is adjusted by the mass flow controller 512. TiCl₄ flows from the gas supply piping 310 and a flow rate thereof is adjusted by the mass flow controller 312. TiCl₄ is vaporized in the vaporizer 700 and mixed with the carrier gas whose flow rate has been adjusted. The mixed gas is exhausted from the exhaust piping 231 while being supplied into the processing chamber 201 through the gas supply holes 410a of the nozzle 410. In this instance, the internal pressure of the processing chamber 201 is maintained in a range of 20 to 50 Pa, for example, at 30 Pa, by appropriately regulating the APC valve 243. A supply amount of TiCl₄ controlled by the mass flow controller 312 is 1.0 to 2.0 g/min. A time over which to expose the wafers 200 to TiCl₄ is 3 to 10 seconds. The temperature of the heater 207 in this instance is set so that the temperature of the wafers 200 falls within a range of 300° C. to 550° C., for example, at 450° C.

The gases flowing inside the processing 201 in this instance are TiCl₄ and the inert gas, such as N₂ and Ar, alone and NH₃ is absent. Hence, TiCl₄ does not undergo a gas phase reaction but undergoes a surface reaction (chemical adsorption) with the surface and the underlying film of each wafer 200 to form an adsorption film of the raw material (TiCl₄) or a Ti layer (hereinafter, referred to as the Ti-containing layer). The term, “adsorption layer of TiCl₄”, referred to herein includes not only a continuous adsorption layer of raw material molecules but also a discontinuous adsorption layer. The term, “Ti layer”, referred to herein includes not only a continuous layer made of Ti but also a Ti thin film formed of a lamination of such continuous layers. A continuous layer made of Ti may occasionally be referred to as a Ti thin film.

By opening the valve 524 to flow an inert gas at the same time from the carrier gas supply piping 520 connected to a midpoint of the gas supply piping 320, it becomes possible to prevent TiCl₄ from flowing around toward NH₃.

### Step 12

A supply of TiCl₄ to the processing chamber 201 is stopped by closing the valve 314 of the gas supply piping 310 and TiCl₄ is flown to the vent line 610 by opening the valve 614. TiCl₄ can be thus supplied to the processing chamber 201 in a stable manner at all times. In this instance, the APC valve 243 of the exhaust piping 231 is kept open to exhaust an atmosphere in the processing chamber 201 by the vacuum pump 246 until the internal pressure drops to 20 Pa or below. Residual TiCl₄ is thus removed out from the processing chamber 201. By supplying an inert gas; such as N₂, into the processing chamber 201 in this instance, the effect of removing residual TiCl₄ can be enhanced further.

### Step 13

In Step 13, NH₃ is flown. NH₃ is flown to the gas supply piping 320 and a carrier gas (N₂) is flown to the carrier gas supply piping 520. The valve 324 of the gas supply piping 320, the valve 524 of the carrier gas supply piping 520, and the APC valve 243 of the exhaust piping 231 are opened all together. The carrier gas flows from the carrier gas supply piping 520 and a flow rate thereof is adjusted by the mass flow controller 522. NH₃ flows from the gas supply piping 320 and a flow rate thereof is adjusted by the mass flow controller 322. NH₃ is mixed with the carrier gas whose flow rate has been adjusted. The mixed gas is exhausted from the exhaust piping 231 while being supplied into the processing chamber 201 through the gas supply holes 420a of the nozzle 420. When NH₃ is flown, the internal pressure of the processing chamber 201 is maintained in a range of 50 to 1000 Pa, for example, at 60 Pa, by appropriately regulating the APC valve 243. A supply flow rate of NH₃ controlled by the mass flow controller 322 is 1 to 10 slm. A time over which to expose the wafers 200 to NH₃ is 10 to 30 seconds. The temperature of the heater 207 in this instance is set to fall within a range of 300° C. to 550° C., for example, at 450° C.

By opening the on-off valve 514 to flow the inert gas at the same time from the carrier gas supply piping 510 connected to a midpoint of the gas supply piping 310, it becomes possible to prevent NH₃ from flowing around toward TiCl₄.

With a supply of NH₃, the chemically adsorbed Ti-containing layer on the wafer 200 and NH₃ undergo a surface reaction (chemical adsorption). A titanium nitride film is thus formed on the wafer 200.

### Step 14

In Step 14, a supply of NH₃ is stopped by closing the valve 324 of the gas supply piping 320. Also, the APC valve 243 of the exhaust piping 231 is kept open to exhaust an atmosphere in the processing chamber 201 by the vacuum pump 246 until the internal pressure drops to 20 Pa or below. Residual NH₃ is thus removed out from the processing chamber 201. In addition, by purging the processing chamber 201 by supplying an inert gas, such as N₂, therein from the gas supply piping 320, which is the NH₃ supply line, and from the gas supply piping 310, which is the TiCl₄ supply line, the effect of removing residual NH₃ can be enhanced further.

Steps 11 through 14 described above are given as one cycle and by carrying out this cycle at least once, a titanium nitride film having a predetermined thickness is formed on the wafer 200 by the ALD method. In this case, attention should be paid so that the film is formed while preventing an atmosphere made of the Ti-containing raw material gas in Step 11 from being mixed with an atmosphere made of a nitriding gas in Step 13 in the processing chamber 201 in each cycle.

It is preferable to adjust the film thickness of the titanium nitride film formed by the ALD method to be about 1 to 5 nm by controlling the number of cycles. The titanium nitride film formed in this instance is a dense continuous film having a smooth surface.

After a titanium nitride film is formed by the ALD method, an annealing processing may be applied to the titanium nitride film using a nitrogen-containing gas, a hydrogen-containing gas, an inert gas, or the like.

Hereinafter, an annealing processing using NH₃ as a nitrogen-containing gas will be described.

A titanium nitride film is modified by exposing the wafer 200 on which the titanium nitride film is formed to an NH₃ atmosphere. To be more concrete, NH₃ is flown to the gas supply piping 320 and a carrier gas (N₂) is flown to the carrier gas supply piping 520. The valve 324 of the gas supply piping 320, the valve 524 of the carrier gas supply piping 520, and the APC valve 243 of the exhaust piping 231 are opened all together. The carrier gas flows from the carrier gas supply piping 520 and a flow rate thereof is adjusted by the mass flow controller 522. NH₃ flows from the gas supply piping 320 and a flow thereof is adjusted by the mass flow controller 322. NH₃ is mixed with the carrier gas whose flow rate has been adjusted. The mixed gas is exhausted from the exhaust piping 231 while being supplied into the processing chamber 201 through the gas supply holes 420a of the nozzle 420.

When NH₃ is flown, the internal pressure of the processing chamber 201 is adjusted to a range of 50 to 1000 Pa, for example, at 150 Pa by appropriately regulating the APC valve 243. A supply flow rate of NH₃ controlled by the mass flow controller 324 is 1 to 91 slm. A time over which to expose the wafers 200 to NH₃ is 1 to 10 minutes. In this instance, the temperature of the heater 207 is set to a predetermined temperature in a rage of 300° C. to 550° C., for example, at 450° C. By setting the temperature during annealing to be the same as the temperature during film formation, the processing time is shortened and a throughput can be enhanced. By opening the on-off valve 514 to flow an inert gas at the same time from the carrier gas supply piping 510 connected to a midpoint of the gas supply piping 310, it becomes possible to prevent NH₃ from flowing around toward TiCl₄. Owing to a supply of NH₃, there can be achieved an advantage that residual chlorine (Cl) in the film is efficiently removed and it becomes possible to form a high-quality thin film. When NH₃ is used, it is thought that H of NH₃ unites with Cl, it becomes HCl, and it is removed.

After the titanium nitride film is formed by the ALD method, a plasma processing may be applied to the titanium nitride film using a nitrogen-containing gas, a hydrogen-containing gas, an inert gas, or the like. For example, by flowing plasma-activated (plasma-excited) NH₃ as a nitrogen-containing gas, it becomes possible to produce a reactant with higher energy. BY carrying out a modification processing with this reaction product, it is thought that an advantage of enhancing the device characteristics can be achieved. A supply of thermally-activated NH₃ can give rise to a soft reaction and the modification processing described above can be therefore applied softly.

The annealing processing and the plasma processing described above may be carried out at the same time. More specifically, the processings are applied to the titanium nitride film by flowing, for example, plasma-activated NH₃ while setting the heater 207 to the temperature during annealing described above. It should be noted, however, that a time over which to active NH₃ with thermal energy and a time over which to activate NH₃ with plasma while maintaining the heater 207 at the temperature during annealing are not necessarily the same length.

A gas used in at least one of the annealing processing and the plasma processing can be a nitrogen-containing gas, a hydrogen-containing gas, an inert gas, or the like. As the nitrogen-containing gas, for example, N₂, NH₃, and monomethyl hydrazine (CH₆N₂) are available. As the hydrogen-containing gas, for example, H₂ is available. As the inert gas, for example, argon (Ar) and helium (He) are available. It is more preferable to use N₂ or NH₃ because they are gas seeds used in the film formation process and there is no need to provide a new gas supply mechanism in this case.

### (2) Second Film Formation Process (Simultaneous Supply Process)

In a second film formation process, a case where film is formed on a substrate by the CVD method will be described.

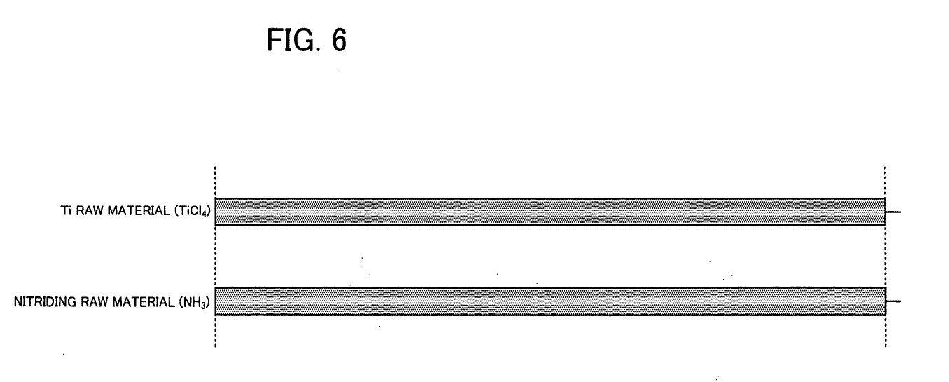

FIG. 6 shows a film formation sequence of a titanium nitride film in the second film formation process of this embodiment. In order to deposit a titanium nitride film by the CVD method, the controller 280 controls the valves, the mass flow controllers, the vacuum pump, and so forth so that TiCl₄ and NH₃ are supplied into the processing chamber 201 in such a manner that there is timing at which both are present simultaneously for a gas phase reaction (CVD reaction) to take place. Hereinafter, the more concrete film formation sequence will be described.

In this process, TiCl₄ and NH₃ are flown simultaneously. TiCl₄ is flown to the gas supply piping 310 and a carrier gas (N₂) is flown to the carrier gas supply piping 510. The valve 314 of the gas supply piping 310, the valve 514 of the carrier gas supply piping 510, and the APC valve 243 of the exhaust piping 231 are opened all together. The carrier gas flows from the carrier gas supply piping 510 and a flow rate thereof is adjusted by the mass flow controller 512. TiCl₄ flows from the gas supply piping 310 and a flow rate thereof is adjusted by the mass flow controller 312. TiCl₄ is vaporized in the vaporizer 700 and mixed with the carrier gas whose flow rate has been adjusted. The mixed gas is supplied into the processing chamber 201 through the gas supply holes 410a of the nozzle 410.

Also, NH₃ is flown to the gas supply piping 320 and a carrier gas (N₂) is flown to the carrier gas supply piping 520. The valve 324 of the gas supply piping 320, the valve 524 of the carrier gas supply piping 520, and the APC valve 243 of the exhaust piping 231 are opened all together. The carrier gas flows from the carrier gas supply piping 520 and a flow rate thereof is adjusted by the mass flow controller 522. NH₃ flows from the gas supply piping 320 and a flow rate thereof is adjusted by the mass flow rate controller 322. NH₃ is mixed with the carrier gas whose flow rate has been adjusted. The mixed gas is supplied into the processing chamber 201 through the gas supply holes 420a of the nozzle 420.

Then, TiCl₄ and NH₃ supplied into the processing chamber 201 are exhausted from the exhaust piping 231. In this instance, the internal pressure of the processing chamber 201 is maintained in a range of 10 to 30 Pa, for example, at 20 Pa, by appropriately regulating the APC valve 243. A supply amount of TiCl₄ controlled by the mass flow controller 312 is 0.1 to 1.0 g/min. A supply amount of NH₃ controlled by the mass flow controller 322 is 0.1 to 0.5 slm. A time over which to expose the wafers 200 to TiCl₄ and NH₃ is a time needed to reach a desired film thickness. The temperature of the heater 207 in this instance is set to fall within a range of 300° C. to 550° C., for example, at 450° C.

Herein, the heater temperature is set to be substantially the same in the first film formation process and the second film formation, and the heater temperature is set to 450° C. in this case. By setting the temperature to be substantially the same and carrying out the processing in situ, the processing time can be shortened. Hence, there can be achieved an advantage that the productivity of the semiconductor device can be increased. Conversely, it is also possible to actively vary the temperature so that such a temperature is set as the most suitable condition of the ALD method or the CVD method. For example, the processing temperature by the ALD method may be set lower than the processing temperature by the CVD method.

The gases flowing through the processing chamber 201 in this instance are TiCl₄, NH₃, and an inert gas, such as N₂ and Ar. TiCl₄ and NH₃ therefore undergo a gas phase reaction (thermal CVD reaction). A thin film having a predetermined film thickness is thus deposited on the surface and the underlying film of each wafer 200 (deposition).

When a pre-set processing time has elapsed, a supply of TiCl₄ and NH₃ is stopped by closing the valve 314 of the gas supply piping 310 and the valve 324 of the gas supply piping 320. In this instance, the APC valve 243 of the exhaust piping 231 is kept open to exhaust an atmosphere in the processing chamber 201 by the vacuum pump 246 until the internal pressure drops to 20 Pa or below. Residual TiCl₄ and NH₃ are thus removed out from the processing chamber 201. In addition, by supplying the inert gas into the processing chamber 201 in this instance while the valve 514 of the gas supply piping 510 and the valve 524 of the gas supply piping 520 are kept open, the effect of removing residual TiCl₄ and NH₃ can be enhanced further.

When the film formation processing to form a titanium nitride film having a predetermined film thickness has been applied, the processing chamber 201 is purged with an inert gas, such as a N₂ gas, as the inert gas is exhausted while being supplied into the processing chamber 201 (gas purge). Subsequently, an atmosphere in the processing chamber 201 is displaced by the inert gas (inert gas displacement) and the internal pressure of the processing chamber 201 restores to normal pressure (atmosphere restoration). Subsequently, the seal cap 219 is moved down by the boat elevator 115. The lower end of the reaction tube 203 is thus opened and the treated wafers 200 being supported on the boat 217 are carried out to the outside of the reaction tube 203 from the lower end of the reaction tube 203 (boat unload). Subsequently, the treated wafers 200 are discharged from the boat 217 (wafer discharge). A single film formation processing (batch processing) is thus ended.

The film thickness of the titanium nitride film by the CVD method is adjusted by a supply time. The film can be thicker as the supply time becomes longer and the film can be thinner as the supply time becomes shorter.

After the titanium nitride film is formed by the CVD method, an annealing processing or a plasma processing may be applied to the titanium nitride film using argon (Ar), helium (He), or the like, all of which are an inert gas.

Further, an annealing processing or a plasma processing may be applied to the titanium nitride film by using N₂, NH₃, or monomethyl hydrazine (CH₆N₂) as a gas containing nitrogen atoms.

Furthermore, an annealing processing or a plasma processing may be applied to the titanium nitride film by using H₂ or the like as a gas containing hydrogen atoms.

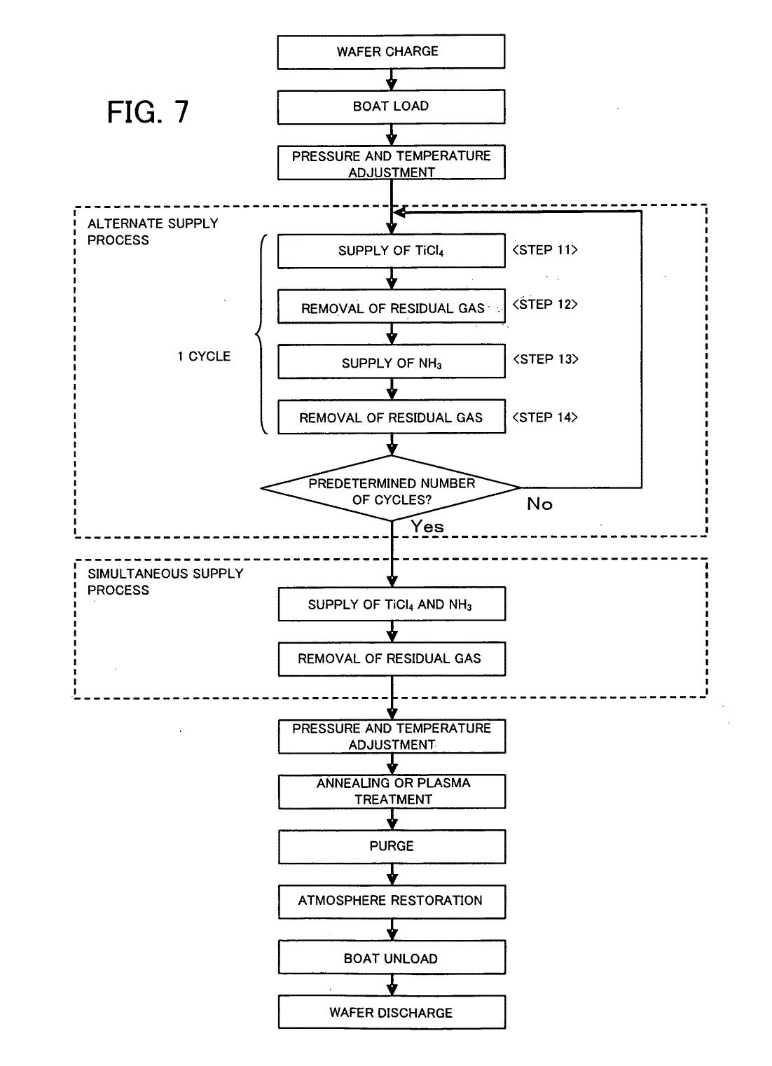

FIG. 7 shows an example of a control flow in a case where an annealing processing or a plasma processing is applied after the CVD film formation described above. As is shown in FIG. 7, it is preferable to apply an annealing processing or a plasma processing before the interior of the processing chamber 201 is purged with an inert gas (gas purge) and after the internal pressure and temperature of the processing chamber 201 are adjusted after the simultaneous supply process in the control flow of this embodiment depicted in FIG. 4.

As has been described above, by forming the titanium nitride film on the substrate by the CVD method as the second process after the titanium nitride film is formed on the substrate by the ALD method as the first film formation process, the titanium nitride films can be formed on the substrate by different film formation methods in the same processing chamber.

The reason why an ALD layer formed by the ALD method is formed in the first film formation process is to form a dense continuous film having a smooth surface. By depositing a film as the ALD layer, it becomes possible to suppress non-uniformity in film thickness and morphology deterioration resulting from in-plane non-uniformity at an incubation time when depositing a CVD layer formed by the CVD method. In addition, it becomes possible to suppress deterioration in film quality caused by inhomogeneous growth at the beginning of CVD layer deposition.

The reason why a CVD layer is formed in the second film formation process is to shorten the time needed to obtain a predetermined film thickness by using a growth rate faster than that of the ALD layer. Also, by changing the film formation condition, it becomes possible to control the film quality of a film to be deposited.

Also, by forming a high-density continuous film by the ALD film formation at the beginning of film formation by carrying out ALD film formation once first and then CVD film formation once, it becomes possible to prevent random growth of crystal grains in the following CVD film formation. Consequently, a dense titanium nitride film having a smooth surface can be formed at a high deposition rate.

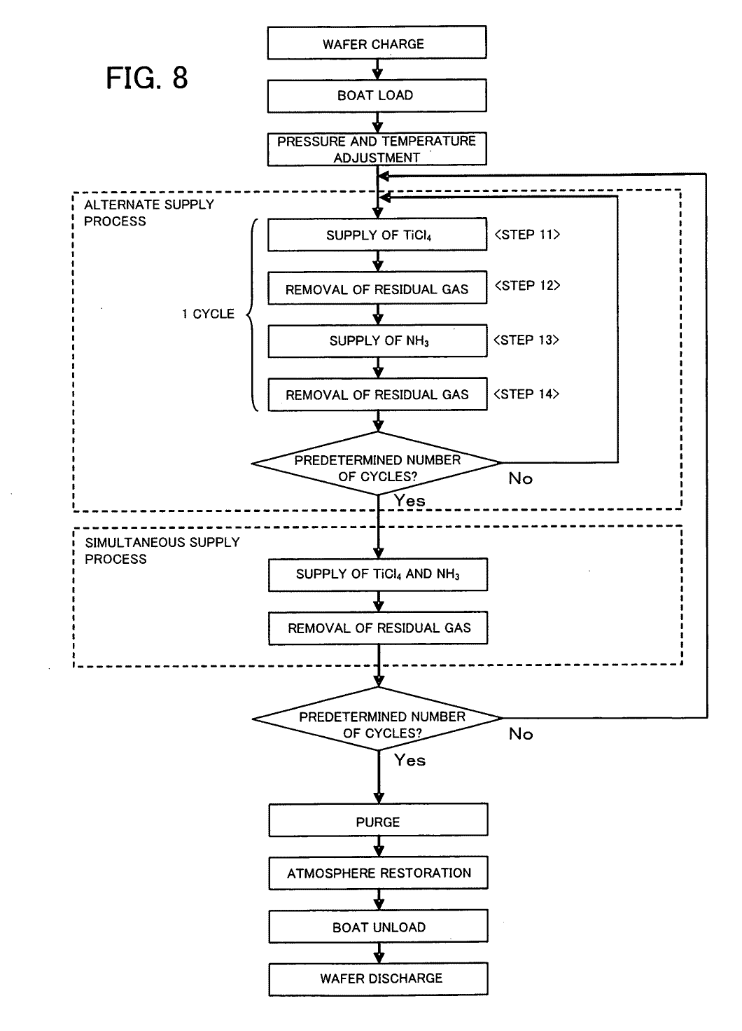

FIG. 8 shows a case where respective film formation methods are carried out alternately more than once by carrying out ALD film formation first and then the CVD method film formation. Accordingly, by forming films repetitively by changing the film formation methods periodically, it becomes possible to prevent crystal grains from becoming bulky and a smooth and dense surface can be obtained even when a thick film is formed. In addition, by combining the ALD method that is excellent in a step coverage and the CVD method that is not, it becomes possible to control the coverage property.

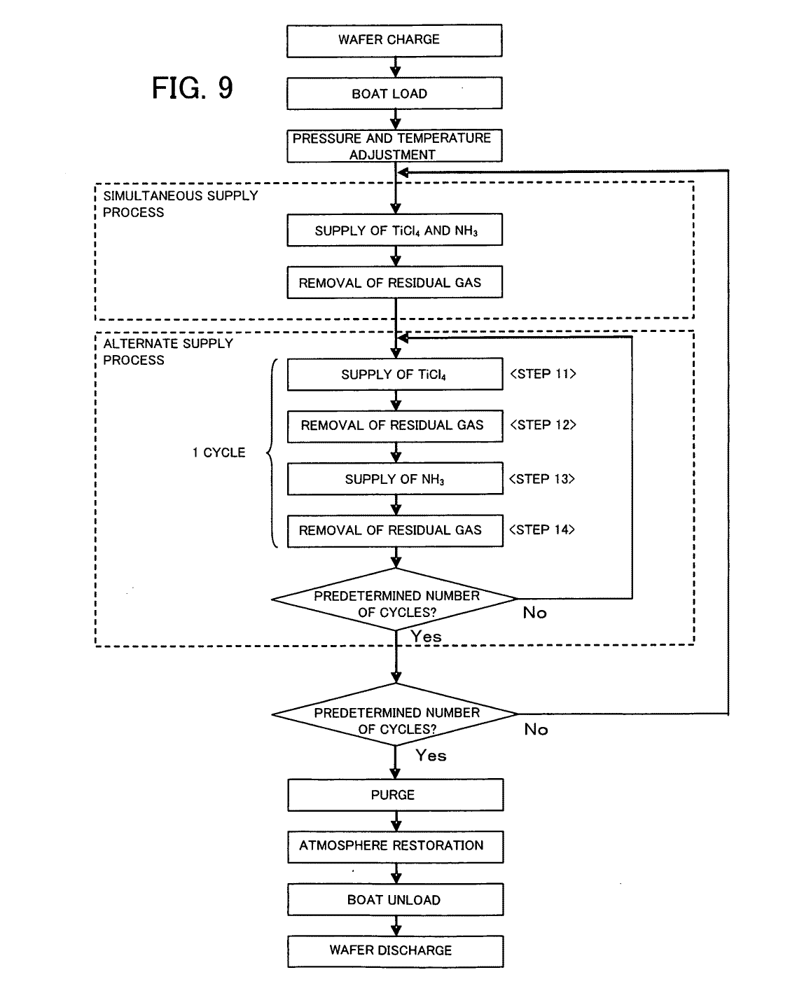

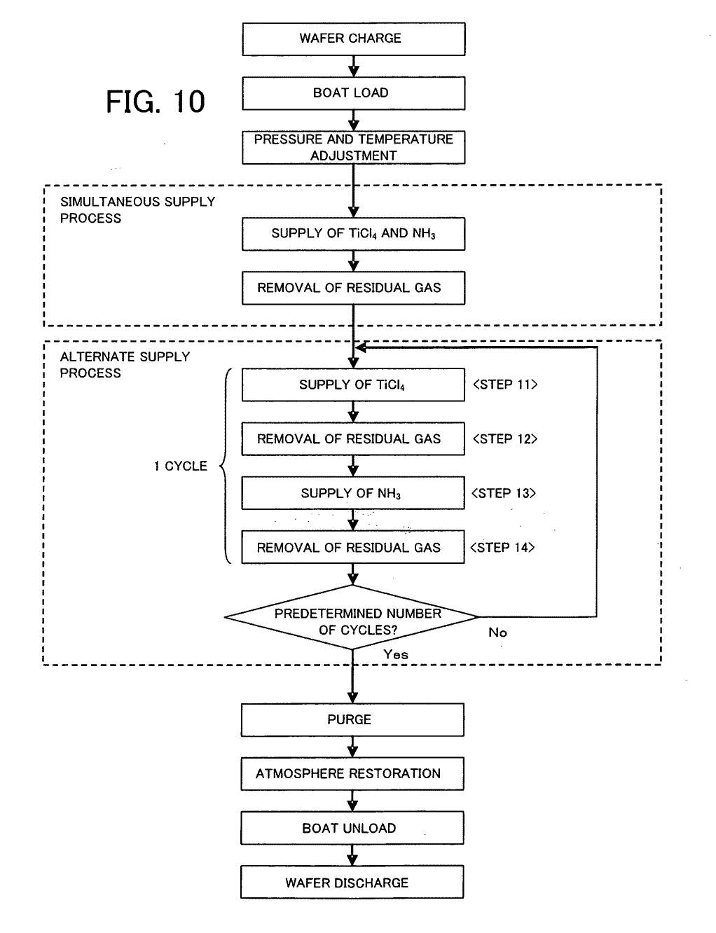

FIG. 9 shows a case where respective film formation methods are performed alternately more than once by carrying out CVD film formation first and then ALD film formation. FIG. 10 shows a case where CVD film formation is carried out once first and then ALD film formation once. In this manner, it may be configured in such a manner that a CVD layer is formed in the first film formation process and an ALD layer is formed in the second film formation process. Because it is thought that the ALD layer has an effect of stopping growth of random pillar-like grains in the CVD layer, there can be achieved advantages, such as an improvement of the surface morphology, an improvement of the film quality like specific resistance, and enhancement of a growth rate.

A desired film thickness may be obtained by forming ALD layers and CVD layers more than once. In this case, the ALD layers and the CVD layers may be deposited alternately in order or deposited in no particular order. Film thicknesses of the respective ALD layers and CVD layers are adjusted as needed.

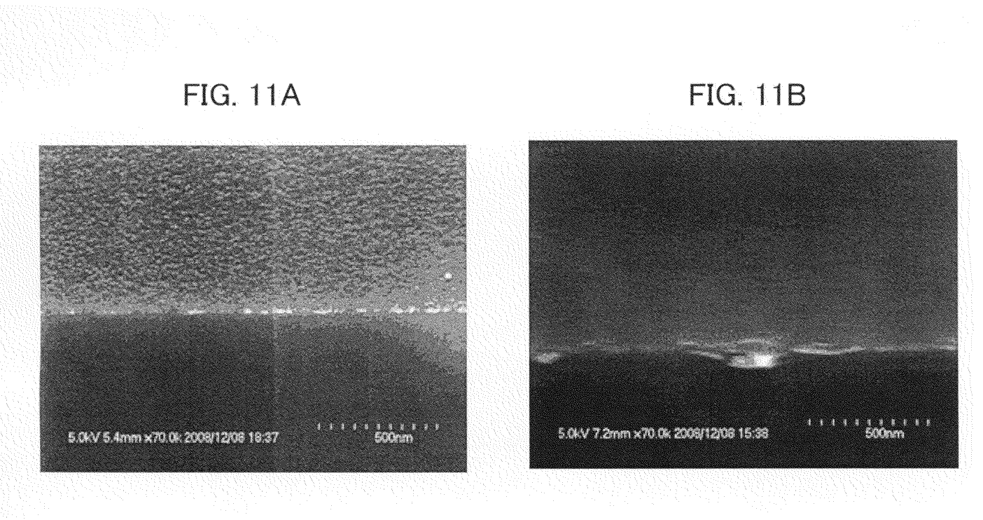

FIG. 11A shows a case where a film is formed by depositing a single CVD layer alone and FIG. 11B shows a case where a film is formed by depositing an ALD layer and a CVD layer continuously, both on a bare silicon substrate at 450° C. for comparison of the surface morphology. Data was acquired by an observation using an SEM (Scanning Electron Microscope). It can be understood from FIG. 11A and FIG. 11B that a smoother surface can be obtained in the case of the invention where a film is formed by depositing an ALD layer and a CVD layer continuously.

### Second Embodiment

Only differences from the first embodiment above will be described in this embodiment.

In the first embodiment above, the titanium nitride film is formed as an ALD layer in the first film formation process by using TiCl₄ as a Ti raw material and NH₃ as a nitriding raw material. In this embodiment, however, a film is formed by dividing the first film formation process to a titanium nitride film formation process by which a titanium nitride film is formed and an aluminum nitride film formation process by which an aluminum nitride film is formed. The second film formation process is the same as the counterpart in the first embodiment above.

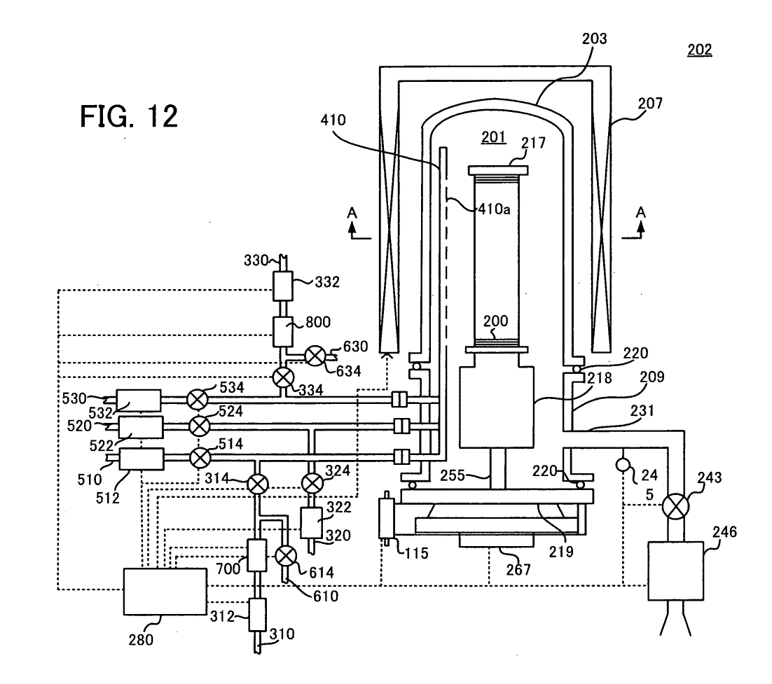

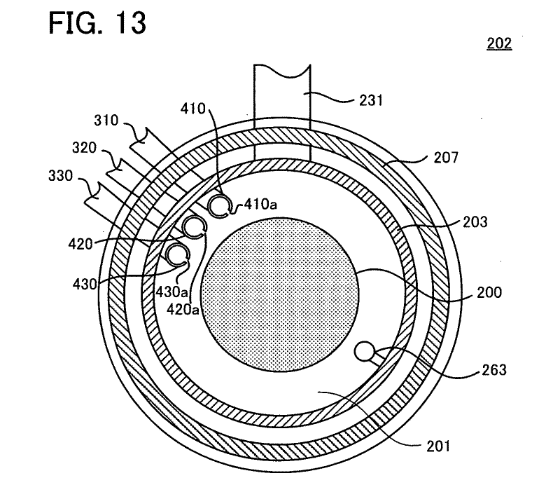

A substrate processing apparatus suitably used in this embodiment will be described using FIG. 12 and FIG. 13. Differences from FIG. 2 and FIG. 3 are that a gas supply piping 330 (third gas supply piping 330) is further connected to the processing chamber 201 in order to supply an Al raw material as a raw material gas to form an aluminum nitride film.

The gas supply piping 330 is provided with, sequentially from the upstream end, a mass flow controller 332, which is a flow rate control device (flow rate control means), a vaporizer 800, which is a vaporization unit (vaporization means), and a valve 334, which is an on-off valve. A nozzle 430 (third nozzle 430) is coupled to the tip end of the gas supply piping 330. The nozzle 430 extends in a top-bottom direction (loading direction of the wafers 200) along the inner wall of the reaction tube 203 in a circular space between the inner wall of the reaction tube 203 forming the processing chamber 201 and the wafers 200. A large number of gas supply holes 430a through which to supply a raw material gas are provided to the side surface of the nozzle 430. The gas supply holes 430a have opening areas from bottom to top in the same size or in progressively increasing sizes at the same opening pitch.

Further, the gas supply piping 330 is provided with a vent line 630 connected to the exhaust piping 231 and a valve 634 both disposed between the vaporizer 800 and the valve 334. In a case where a raw material gas is not supplied to the processing chamber 201, the raw material gas is supplied to the vent line 630 via the valve 634.

Examples of an Al raw material include but not limited to trimethyl aluminum (TMA, (CH₃)₃Al) and aluminum trichloride (AlCl₃).

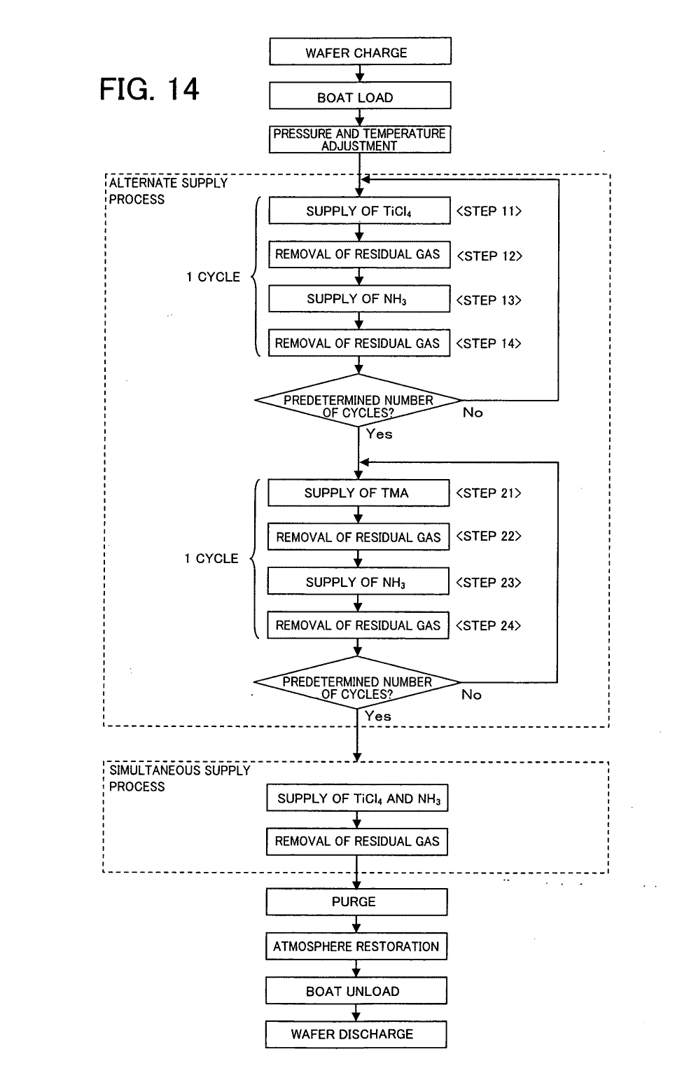

FIG. 14 shows an example of a control flow in the second embodiment.

### (1) First Film Formation Process (Alternate Supply Process)

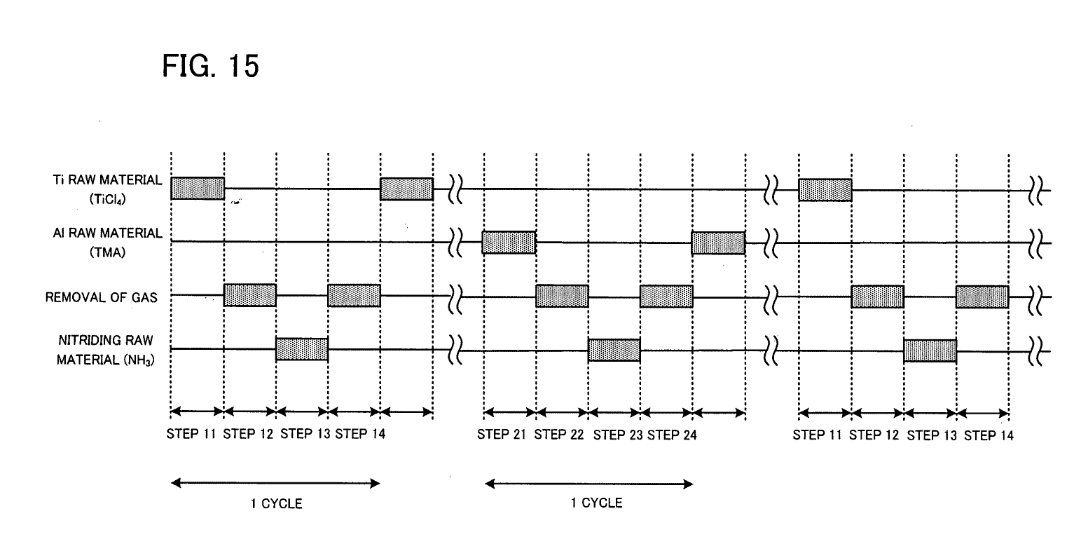

FIG. 15 shows a sequence in the first film formation process of this embodiment.

A titanium nitride film is first formed to have a predetermined film thickness by carrying out Steps 11 through 14 making up one cycle in the first embodiment above while controlling the number of cycles. Subsequently, an aluminum nitride film is formed to have a predetermined film thickness by carrying out Steps 21 through 24 making up one cycle described below while controlling the number of cycles.

### Step 21

A difference from Step 11 above is that TMA, which is an Al raw material, is used instead of TiCl₄. The other conditions are the same as those of the case using TiCl₄.

The gases flowing through the processing chamber 201 in this instance are TMA, and an inert gas, such as N₂ and Ar, alone and NH₃ is absent. Accordingly, TMA does not undergo a gas phase reaction but undergoes a surface reaction (chemical adsorption) with the surface and the underlying film of each wafer 200 to form an adsorption layer of the raw material (TMA) or an Al layer (hereinafter, referred to as the Al-containing layer). The term, “adsorption layer of TMA”, referred to herein includes not only a continuous adsorption layer of raw material molecules but also a discontinuous adsorption layer. The term, “Al layer”, referred to herein includes not only a continuous layer made of Al but also an Al thin film formed of a lamination of such continuous layers. A continuous layer made of Al may occasionally be referred to as an Al thin film.

By opening the valve 514 and the valve 524 to flow an inert gas at the same time from the carrier gas supply piping 510 connected to a midpoint of the gas supply piping 310 and from the carrier gas supply piping 520 connected to a midpoint of the gas supply piping 320, it becomes possible to prevent TMA from flowing around toward NH₃ and TiCl₄.

### Step 22

A supply of TMA to the processing chamber 201 is stopped by closing the valve 334 of the gas supply piping 330 and TMA is flown to the vent line 630 by opening the valve 634. TMA can be thus supplied to the processing chamber 201 in a stable manner at all times. In this instance, the APC valve 243 of the exhaust piping 231 is kept open to exhaust an atmosphere in the processing chamber 201 by the vacuum pump 246. Residual TMA is thus removed out from the processing chamber 201. By supplying an inert gas, such as N₂, into the processing chamber 201 in this instance, an effect of removing residual TMA can be enhanced further.

### Step 23

In Step 23, NH₃ is flown. Because the conditions are the same as those in Step 13 above, a description is omitted herein. By opening the on-off valve 514 and the on-off valve 534 to flow an inert gas simultaneously with a supply of NH₃ from the carrier gas supply piping 510 connected to a midpoint of the gas supply piping 310 and from the carrier gas supply piping 530 connected to a midpoint of the gas supply piping 330, it becomes possible to prevent NH₃ from flowing around toward TiCl₄ and TMA.

With a supply of NH₃, an Al-containing layer chemically adsorbed onto the wafer 200 and NH₃ undergo a surface reaction (chemical adsorption). An aluminum nitride film is thus formed on the wafer 200.

### Step 24

In Step 24, a supply of NH₃ is stopped by closing the valve 324 of the gas supply piping 320. Also, the APC valve 234 of the exhaust piping 231 is kept open to exhaust an atmosphere in the processing chamber 201 by the vacuum pump 246. Residual NH₃ is thus removed out from the processing chamber 201. Also, by supplying an inert gas, such as N₂, to the processing chamber 201 in this instance to purge the processing chamber 201, an effect of removing residual NH₃ can be enhanced further. Because the conditions in this instance are the same as those in Step 14 above, a description is omitted herein.

By carrying out Steps 21 through 24 making up one cycle described above at least once, an aluminum nitride film having a predetermined film thickness is formed on the wafer 200 by the ALD method. In this case, as has been mentioned above, attention should be paid so that that a film is formed while preventing an atmosphere made of an Al-containing raw material gas in Step 21 from being mixed with an atmosphere made of a nitriding gas in Step 23 in the processing chamber 201 in each cycle.

More specifically, a titanium nitride film is first formed to have a predetermined film thickness by carrying out Steps 11 through 14 making up one cycle in the first embodiment above while controlling the number of cycles and then an aluminum nitride film is formed to have a predetermined film thickness by carrying out Steps 21 through 24 making up one cycle described above while controlling the number of cycles.

By forming a titanium nitride film by further carrying out Steps 11 through 14 a predetermined number of times as needed after an aluminum nitride film having a predetermined film thickness is formed, a laminated film of the titanium nitride film and the aluminum nitride film can be formed.

By making the laminated structure as above, it becomes possible to control a composition ratio of Ti/Al/N by controlling a film thickness ratio of the respective films.

Also, by changing a film formation order of the titanium nitride film and the aluminum nitride film, it becomes possible to control a reaction at the interface with the underlying film and to control the upper and lower interfaces, such as enhancing the resistance to oxidation at the upper interface.

### Third Embodiment

Only differences from the first embodiment above will be described in this embodiment. In the first embodiment above, TiCl₄ as a Ti raw material and NH₃ as a nitriding raw material are simultaneously supplied to the processing chamber 201 continuously during a reaction in the second film formation process to form a CVD layer. This embodiment is different in that raw materials are supplied to the processing chamber 201 intermittently (in pulses). A substrate processing apparatus suitably used in this embodiment is the same as the counterpart in the first embodiment above.

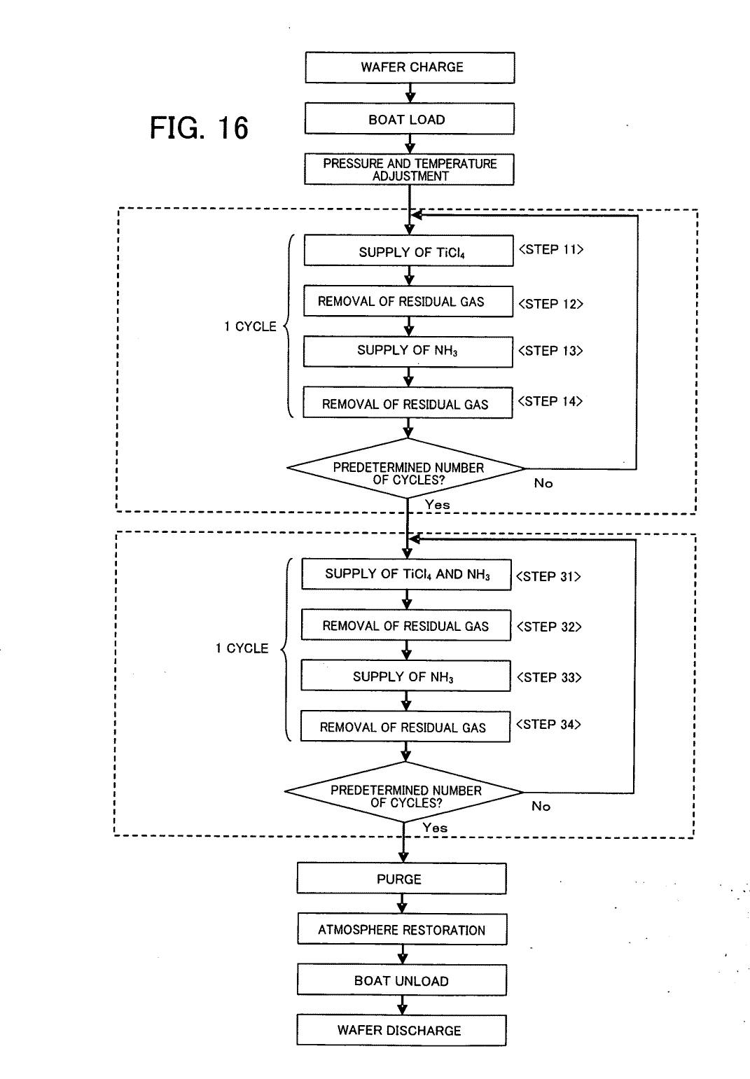

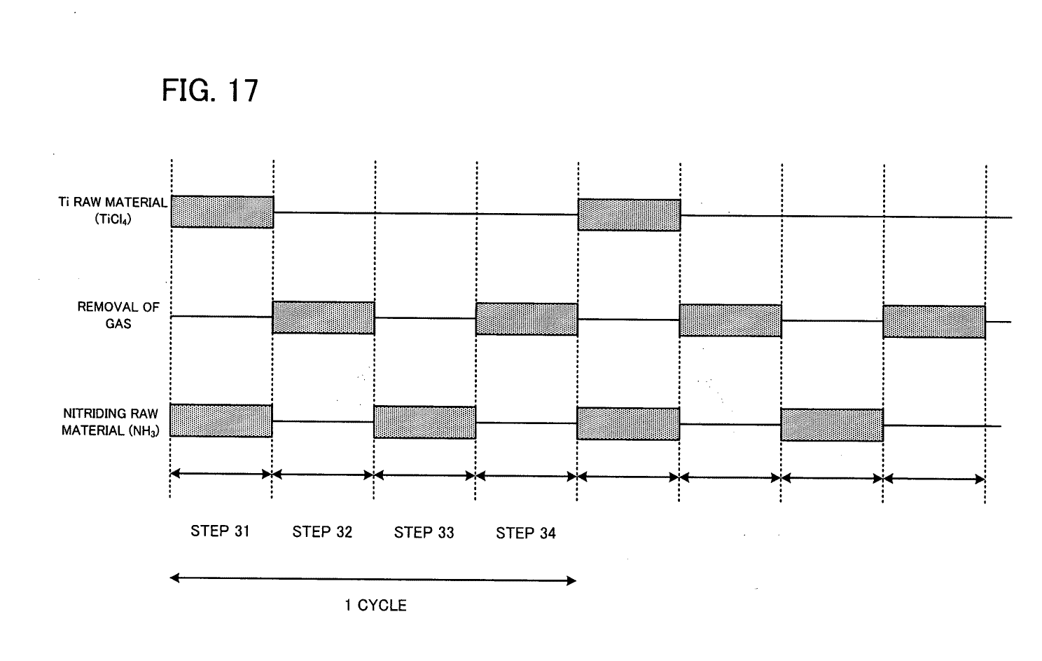

FIG. 16 shows an example of a control flow in the third embodiment. FIG. 17 shows a sequence of the second film formation process in the third embodiment. Hereinafter, the sequence in this embodiment will be described with reference to FIG. 17. It should be noted that the conditions are all the same as those in the first embodiment above.

### Step 31

In Step 31, TiCl₄ and NH₃ are flown simultaneously. TiCl₄ is flown to the gas supply piping 310 and a carrier gas (N₂) is flown to the carrier gas supply piping 510. The valve 314 of the gas supply piping 310, the valve 514 of the carrier gas supply piping 510, and the APC valve 243 of the exhaust piping 231 are opened all together. The carrier gas flows from the carrier gas supply piping 510 and a flow rate thereof is adjusted by the mass flow controller 512. TiCl₄ flows from the gas supply piping 310 and a flow rate thereof is adjusted by the mass flow controller 312. TiCl₄ is vaporized in the vaporizer 700 and mixed with the carrier gas whose flow rate has been adjusted. The mixed gas is supplied into the processing chamber 201 through the gas supply holes 410a of the nozzle 410.

Also, NH₃ is flown to the gas supply piping 320 and a carrier gas (N₂) is flown to the carrier gas supply piping 520. The valve 324 of the gas supply piping 320 and the valve 524 of the carrier gas supply piping 520, and the APC valve 234 of the exhaust piping 231 are opened all together. The carrier gas flows from the carrier gas supply piping 520 and a flow rate thereof is adjusted by the mass flow controller 522. NH₃ flows from the gas supply piping 320 and a flow rate thereof is adjusted by the mass flow controller 322. NH₃ is mixed with the carrier gas whose flow rate has been adjusted. The mixed gas is supplied into the processing chamber 201 through the gas supply holes 420a of the nozzle 420.

TiCl₄ and NH₃ supplied into the processing chamber 201 are exhausted from the exhaust piping 231. The gases flowing through the processing chamber 201 in this instance are TiCl₄, NH₃ and an inert gas, such as N₂ and Ar. TiCl₄ and NH₃ therefore undergo a gas phase reaction (thermal CVD reaction). A thin film having a predetermined film thickness is consequently deposited on the surface and the underlying film of each wafer 200 (deposition).

### Step 32

A supply of TiCl₄ and NH₃ is stopped by closing the valve 314 of the gas supply piping 310 and the valve 324 of the gas supply piping 320. In this instance, the APC valve 243 of the exhaust piping 231 is kept open to exhaust an atmosphere in the processing chamber 201 by the vacuum pump 246. Residual TiCl₄ and NH₃ are thus removed out from the processing chamber 201. By supplying an inert gas, such as N₂, into the processing chamber 201 in this instance, an effect of removing residual TiCl₄ and NH₃ can be enhanced further.

### Step 33

In Step 33, NH₃ alone is flown. NH₃ is flown to the gas supply piping 320 and a carrier gas (N₂) is flown to the carrier gas supply piping 520. The valve 324 of the gas supply piping 320, the valve 524 of the carrier gas supply piping 520, and the APC valve 243 of the exhaust piping 231 are opened all together. The carrier gas flows from the carrier gas supply piping 520 and a flow rate thereof is adjusted by the mass flow controller 522. NH₃ flows from the gas supply piping 320 and a flow rate thereof is adjusted by the mass flow controller 322. NH₃ is mixed with the carrier gas whose flow rate has been adjusted. The mixed gas is exhausted from the exhaust piping 231 while being supplied into the processing chamber 201 through the gas supply holes 420a of the nozzle 420. When NH₃ is flown, the internal pressure of the processing chamber 201 is maintained in a range of 50 to 1000 Pa, for example, at 60 Pa, by appropriately regulating the APC valve 243. A supply flow rate of NH₃ controlled by the mass flow controller 322 is 1.0 to 10.0 slm. A time over which to expose the wafers 200 to NH₃ is 10 to 60 seconds.

By opening the on-off valve 514 to flow an inert gas at the same time from the carrier gas supply piping 510 connected to a midpoint of the gas supply piping 310, it becomes possible to prevent NH₃ from flowing around toward TiCl₄.

With a supply of NH₃, the Ti-containing layer chemically adsorbed onto the wafer 200 and NH₃ undergo a surface reaction (chemical adsorption). A titanium nitride film is thus formed on the wafer 200.

### Step 34

In Step 34, a supply of NH₃ is stopped by closing the valve 324 of the gas supply piping 320. The APC valve 243 of the exhaust piping 231 is kept open to exhaust an atmosphere in the processing chamber 201 by the vacuum pump 246. Residual NH₃ is thus removed out from the processing chamber 201. In this instance, by purging the processing chamber 201 by supplying an inert gas, such as N₂, therein from the gas supply piping 320, which is a NH₃ supply line, and the gas supply piping 310, which is a TiCl₄ supply line, an effect of removing residual NH₃ can be enhanced further.

By carrying out Steps 31 through 34 making up one cycle described above at least once, a titanium nitride film having a predetermined film thickness is formed on the wafer 200 by the ALD method. In this case, as has been mentioned above, attention should be paid so that that a film is formed while preventing an atmosphere made of a Ti-containing raw material gas and a nitriding gas in Step 31 from being mixed with an atmosphere made of a nitriding gas in Step 33 in the processing chamber 201 in each cycle.

More specifically, a titanium nitride film is first formed to have a predetermined film thickness by carrying out Steps 11 through 14 making up one cycle in the first embodiment above while controlling the number of cycles, and then a titanium nitride film is formed to have a predetermined film thickness by carrying out Steps 31 through 34 making up one cycle described above while controlling the number of cycles.

### Fourth Embodiment

Only differences from the first embodiment above will be described in this embodiment.

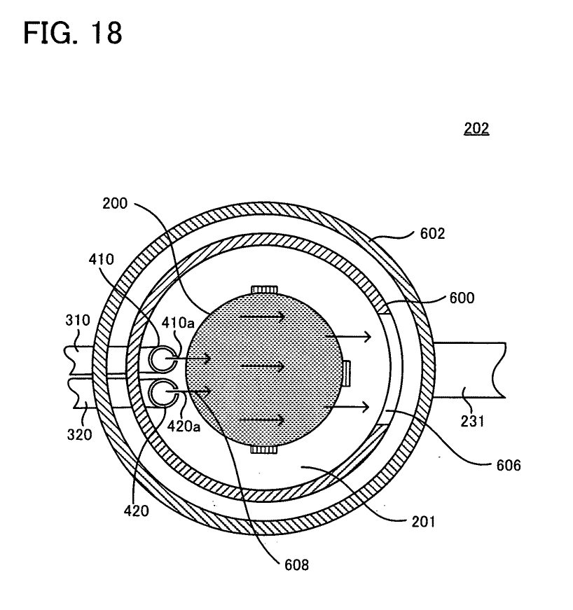

FIG. 18 is a transverse cross section of the processing furnace in a fourth embodiment of the invention.

A processing furnace 202 of this embodiment is provided with an inner tube 600 in which to accommodate the wafers 200 as substrates and an outer tube 602 that surrounds the inner tube 600. A pair of gas nozzles 410 and 420 is provided inside the inner tube 600. A large number of gas supply holes 410a and 420a through which to supply raw material gases are provided to the side surfaces of a pair of the gas nozzles 410 and 420, respectively. A gas exhaust port 606 is provided to the side wall of the inner tube 600 at a position opposing the gas supply holes 410a and 420a with the wafers 200 in between. An exhaust piping 231 that exhausts an atmosphere in a space sandwiched between the outer tube 602 and the inner tube 600 is connected to the outer tube 602. Gases are supplied into the inner tube 600 through the gas supply holes 410a and 420a and an atmosphere in the space sandwiched between the outer tube 602 and the inner tube 600 is exhausted by the exhaust piping 231 while the wafers 200 are kept rotated in a horizontal posture. A gas flow 608 in a horizontal direction heading toward the gas exhaust port 606 from the gas supply holes 410a and 420a is thus generated inside the inner tube 600. Accordingly, the gases are supplied to the wafers 200 in a horizontal direction to form a thin film on each (side flow/side vent method).

The phrase, “TiCl₄ and NH₃ are supplied simultaneously into the processing chamber”, referred to herein means a state where TiCl₄ and NH₃ are present simultaneously in the processing chamber merely at a given moment and both are not necessarily provided at exactly the same timing. In other words, it may be configured in such a manner that either one of the gases is supplied and the other gas is supplied later or a supply of either one of the gases is stopped first and a supply of the other gas is stopped after the supply of the other gas alone is continued for a while.

It is preferable to adjust a film thickness of the titanium nitride film by the ALD method to about 1 to 5 nm by controlling the number of cycles. The titanium nitride film formed in this instance is a dense continuous film having a smooth surface.

After the titanium nitride film is formed by the ALD method, an annealing processing or a plasma processing may be applied to the titanium nitride film using argon (Ar) or helium (He), both of which are an inert gas.

Further, an annealing processing or a plasma processing may be applied to the titanium nitride film using N₂, NH₃, or monomethyl hydrazine (CH₆N₂) as a gas containing nitrogen atoms.

Furthermore, an annealing processing or a plasma processing may be applied to the titanium nitride film using H₂ or the like as a gas containing hydrogen atoms.

According to the invention, it becomes possible to form a dense, low-resistive titanium nitride film having a smooth surface at a higher rate and the substrate temperature, for example, of 450° C.

Also, it becomes possible to provide a titanium nitride film having a better quality in comparison with a titanium nitride film formed by the CVD method at a higher deposition rate, that is, at a higher productivity, in comparison with a titanium nitride film formed by the ALD method.

In addition, because it becomes possible to form a high-quality thin film at a low temperature, a thermal budget can be reduced.

Further, it becomes possible to provide a film formed by the ALD method as a laminated film formed of an ultra-thin laminated film having a lamination of films of different composites, for example, a titanium nitride film and an aluminum nitride film, and a thin film having the same composite as at least one of the films forming the laminated film, at a high quality and a high productivity.

According to one aspect of the invention, it becomes possible to provide a satisfactory film that strongly reflects the characteristic of a satisfactory underlying film while maintaining a high productivity.

According to the invention, a film formed at 450° C. or below and having a film thickness of 30 nm or less is a conducting film having a specific resistance of 200 μΩ·cm or less.

It should be appreciated that the invention is not based on the premise of using a vertical apparatus, and for example, a horizontal apparatus can be used as well. The invention is not based on the premise of using a batch apparatus configured to apply a processing to a plurality of subject substrates at a time, either, and a sheet-fed apparatus can be used as well.

The formation of the titanium nitride film using TiCl₄ and NH₃ has been described as embodiments. It should be appreciated, however, that the invention is not limited to this film formation. The invention is also applicable to pure metal or a metal film compound formed by letting one of an inorganic metal compound and an organic metal compound react with a gas that has reactivity to these metal compounds.

Low resistivity can be achieved in a more stable manner by using an inorganic metal compound, which is an inorganic raw material, such as TiCl₄.

In the embodiments above, a lamination of a titanium nitride film and an aluminum nitride film has been described as an example of a laminated film having a laminated structure. It should be appreciated, however, that the invention is not limited to this example and is also applicable to other types of film seeds.

Pure metal or a metal compound formed in the invention can be used as a gate electrode material for MOS transistor. Further, the gate electrode material for MOS transistor may be formed on the ground of a three-dimensional shape.

Also, pure metal or a metal compound formed in the invention can be used as a lower or upper electrode material for capacitor.

### DESCRIPTION OF PREFERRED ASPECTS OF THE INVENTION

Hereinafter, preferred aspects of the invention will be described.

### Additional Note 1

A method of manufacturing a semiconductor device according to an aspect of the invention includes the steps of carrying out an alternate supply process by which a metal film is formed on a substrate by alternately supplying a plurality of gases to a processing chamber so that the gases are not mixed with other, and carrying out a simultaneous supply process by which a metal film is formed on a substrate by simultaneously supplying a plurality of gases to a processing chamber so that the gases are mixed with each other.

### Additional Note 2

It is preferable that the alternate supply process and the simultaneous supply process are carried out continuously in a same processing chamber.

### Additional Note 3

It is preferable that the alternate supply process and the simultaneous supply process are carried out more than once in no particular order.

### Additional Note 4

It is preferable that the alternate supply process and the simultaneous supply process are repeated sequentially more than once.

### Additional Note 5

It is preferable that the plurality of gases include at least one type of a metal compound and a reactant gas that has reactivity to the metal compound.

### Additional Note 6

It is preferable that the metal compound is a titanium-containing gas, the reactant gas is a nitrogen-containing gas, and the metal film is a titanium nitride film.

### Additional Note 7

It is preferable that the titanium-containing gas is a titanium tetrachloride and the nitrogen-containing gas is ammonia.

### Additional Note 8

It is preferable that: the plurality of gases include a first metal compound and a second metal compound; the alternate supply process has a first metal film formation process by which a first metal film is formed on the substrate using the first metal compound and a second metal film formation process by which a second metal film is formed on the substrate using the second metal compound; and the first metal film formation process and the second metal film formation process are carried out at least once.

### Additional Note 9

It is preferable that the first metal compound is a titanium-containing gas, the second metal compound is one of aluminum and nickel, and the reactant gas is a nitrogen-containing gas.

### Additional Note 10

It is preferable that the first metal film is a titanium aluminum nitride film or the second metal film is a titanium nickel nitride film.

### Additional Note 11

It is preferable that, in the simultaneous supply process, a supply of the reactant gas to the processing chamber is stopped after a supply of the metal compound to the processing chamber is stopped.

### Additional Note 12

It is preferable that, in the simultaneous supply process, a heat processing is applied by supplying the reactant gas to the processing chamber again after a supply of the metal compound and the reactant gas to the processing chamber is stopped.

### Additional Note 13

It is preferable that, in the simultaneous supply process, a heat processing is applied by supplying a gas different from the metal compound and the reactant gas to the processing chamber after a supply of the metal compound and the reactant gas to the processing chamber is stopped.

### Additional Note 14

A substrate processing apparatus according to another aspect of the invention includes: a processing chamber that accommodates a substrate, heat means that heats the substrate, metal compound supply means that supplies a metal compound to the processing chamber; reactant gas supply means that supplies a reactant gas that has reactivity to the metal compound to the processing chamber; exhaust means that exhausts an atmosphere in the processing chamber; and a control portion that controls the heat means, the metal compound supply means, the reactant gas supply means, and exhaust means. The control portion carries out an alternate supply process by which a first metal film is formed on the substrate by alternately supplying the metal compound and the reactant gas to the processing chamber so that the metal compound and the reactant gas are not mixed with other, and a simultaneous supply process by which a second metal film is formed on the substrate by simultaneously supplying the metal compound and the reactant gas to the processing chamber so that the metal compound and the reactant gas are mixed with each other, by controlling the heat means, the metal compound supply means, the reactant gas supply means, and the exhaust means, so that a predetermined metal film is formed on the substrate.

### Additional Note 15

It is preferable that the first metal film and the second metal film have a same composite.

### Additional Note 16

It is preferable that the control portion carries out the alternate supply process and the simultaneous supply process more than once in no particular order by controlling the heat means, the metal compound supply means, the reactant gas supply means, and the exhaust means.

### Additional Note 17

It is preferable that the control portion repeats the alternate supply process and the simultaneous supply process sequentially more than once by controlling the heat means, the metal compound supply means, the reactant gas supply means, and the exhaust means.

### Additional Note 18

A substrate processing apparatus according to still another aspect of the invention includes: a processing chamber that accommodates a substrate; heat means that heats the substrate; first metal compound supply means that supplies a first metal compound to the processing chamber; second metal compound supply means that supplies a second metal compound to the processing chamber; reactant gas supply means that supplies a reactant gas that has reactivity to the metal compound to the processing chamber; exhaust means that exhausts an atmosphere in the processing chamber; and a control portion that controls the heat means, the first metal compound supply means, the second metal compound supply means, the reactant gas supply means, and the exhaust means. The control portion carries out a first alternate supply process by which a first metal film is formed on the substrate by alternately supplying the first metal compound and the reactant gas to the processing chamber so that the first metal compound and the reactant gas are not mixed with each other, a second alternate supply process by which a second metal film is formed on the substrate by alternately supplying the second metal compound and the reactant gas to the processing chamber so that the second metal compound and the reactant gas are not mixed with each other, and a simultaneous supply process by which a third metal film is formed on the substrate by simultaneously supplying one of the first metal compound and the second metal compound and the reactant gas to the processing chamber so that the first metal compound and the second metal compound and the reactant gas are mixed with each other, by controlling the heat means, the first metal compound supply means, the second metal compound supply means, the reactant gas supply means, and the exhaust means, so that a predetermined metal film is formed on the substrate.

### Additional Note 19

A semiconductor device according to still another aspect of the invention is fabricated by the method of manufacturing a semiconductor device described above.

### Additional Note 20

A semiconductor device according to still another aspect of the invention is fabricated by the substrate processing apparatus described above.

### Additional Note 21

A method of manufacturing a semiconductor device according to still another aspect of the invention includes the steps of: carrying out an alternate supply process by which a first metal film is formed on a substrate placed in a processing chamber by alternately supplying at least one type of a metal compound that is an inorganic raw material and a reactant gas that has reactivity to the metal compound to the processing chamber more than once; carrying out a simultaneous supply process by which a second metal film is formed on the substrate placed in the processing chamber by simultaneously supplying at least one type of a metal compound that is an inorganic raw material and a reactant gas that has reactivity to the metal compound to the processing chamber once so that the metal compound and the reactant gas are mixed with each other; and carrying out a modification process by which at least one of the first metal film and the second metal film is modified using at least one of the reactant gas and an inert gas after at least one of the alternate supply process and the simultaneous supply process.

### Additional Note 22

A method of manufacturing a semiconductor device according to still another aspect of the invention includes the steps of carrying out an alternate supply process by which a first metal film is formed on a substrate placed in a processing chamber by alternately supplying at least one type of a metal compound and a reactant gas that has reactivity to the metal compound to the processing chamber more than once, and carrying out a simultaneous supply process by which a second metal film is formed on the substrate and that includes a process by which at least one type of a metal compound and a reactant gas that has reactivity to the metal compound are simultaneously supplied to the processing chamber so that the metal compound and the reactant gas are mixed with each other. In the simultaneous supply process, a supply of the metal compound and the reactant gas is stopped to remove an atmosphere in the processing chamber after the metal compound and the reactant gas are supplied simultaneously to the processing chamber so that the metal compound and the reactant gas are mixed with each other, after which the reactant gas is supplied to the processing chamber and atmosphere in the processing chamber is subsequently removed by stopping a supply of the reactant gas.

### Additional Note 23

A method of manufacturing a semiconductor device according to still another aspect of the invention includes the steps of carrying out an alternate supply process by which a first metal film is formed on a substrate placed in a processing chamber by alternately supplying a metal compound that is an inorganic raw material and a reactant gas that has reactivity to the metal compound to the processing chamber more than once, and carrying out a simultaneous supply process by which a second metal film is formed on the substrate placed in the processing chamber by simultaneously supplying at least one type of a metal compound that is an inorganic raw material and a reactant gas that has reactivity to the metal compound to the processing chamber so that the metal compound and the reactant gas are mixed with each other. In the alternate supply process, the first metal film is a laminated film of a third metal film and a fourth metal film formed by carrying out, a predetermined number of times, a process by which the third metal film is formed on the substrate by alternately supplying a first metal compound and the reactant gas to the processing chamber more than once and a process by which the fourth metal film is formed on the substrate by alternately supplying a second metal compound that is different from the first metal compound and the reactant gas to the processing chamber more than once.

### Additional Note 24

A method of manufacturing a semiconductor device according to still another aspect of the invention includes the steps of carrying out an alternate supply process by which a first metal film is formed on a substrate placed in a processing chamber by alternately supplying at least one type of a metal compound that is an inorganic raw material and a reactant gas that has reactivity to the metal compound to the processing chamber more than once, and carrying out a simultaneous supply process by which a second metal film is formed on the substrate placed in the processing chamber by simultaneously supplying at least one type of a metal compound that is an inorganic raw material and a reactant gas that has reactivity to the metal compound to the processing chamber once so that the metal compound and the reactant gas are mixed with each other.

### Additional Note 25

It is preferable that at least one type of the metal compound used in each of the alternate supply process and the simultaneous supply process contains same metal.

### Additional Note 26

It is preferable that the reactant gas used in each of the alternate supply process and the simultaneous supply process is same.

### Additional Note 27

It is preferable that the first metal film and the second metal film have a same element composite.

### Additional Note 28

It is preferable that the alternate supply process and the simultaneous supply process are carried out continuously in a same processing chamber while the processing chamber is heated substantially at a same temperature.

### Additional Note 29

It is preferable that the alternate supply process and the simultaneous supply process are carried out alternately more than once.

### Additional Note 30

It is preferable that after at least one of the alternate supply process and the simultaneous supply process is carried out, a heat processing is applied to the substrate on which at least one of the first metal film and the second metal film is formed.

### Additional Note 31

It is preferable that after at least one of the alternate supply process and the simultaneous supply process is carried out, a plasma processing is applied to the substrate on which at least one of the first metal film and the second metal film is formed.

### Additional Note 32

It is preferable that the metal compound that is an inorganic raw material and the reactant gas used in each of the alternate supply process and the simultaneous supply process are TiCl₄ and NH₃, respectively.

### Additional Note 33

A substrate processing apparatus according to still another aspect of the invention includes: a processing chamber that accommodates a substrate; a metal compound supply system that supplies at least one type of a metal compound that is an inorganic raw material to the processing chamber; a reactant gas supply system that supplies a reactant gas that has reactivity to the metal compound to the processing chamber; an exhaust system that exhausts an atmosphere in the processing chamber; and a control portion that controls the metal compound supply system, the reactant gas supply system, and the exhaust system. The control portion carries out an alternate supply process by which a first metal film is formed on the substrate by alternately supplying the metal compound and the reactant gas to the processing chamber more than once and a simultaneous supply process by which a second metal film is formed on the substrate by simultaneously supplying the metal compound and the reactant gas to the processing chamber once so that the metal compound and the reactant gas are mixed with each other, by controlling the metal compound supply system, the reactant gas supply system, and the exhaust system, so that a predetermined metal film is formed on the substrate.

What is claimed is:

1. A method of manufacturing a semiconductor device, comprising:
forming a first metal film on a substrate placed in a processing chamber by alternately supplying at least one type of a metal compound that is an inorganic raw material and a reactant gas that has reactivity to the metal compound to the processing chamber more than once;
forming a second metal film on the substrate by simultaneously supplying at least one type of a metal compound that is an inorganic raw material and a reactant gas that has reactivity to the metal compound to the processing chamber once so that the metal compound and the reactant gas are mixed with each other; and
modifying at least one of the first metal film and the second metal film using at least one of the reactant gas and an inert gas after at least one of forming a first metal film and forming a second metal film.

2. A method of manufacturing a semiconductor device comprising:
forming a first metal film on a substrate placed in a processing chamber by alternately supplying at least one type of a metal compound and a reactant gas that has reactivity to the metal compound to the processing chamber more than once; and
forming a second metal film on a substrate by simultaneously supplying at least one type of a metal compound and a reactant gas that has reactivity to the metal compound to the processing chamber so that the metal compound and the reactant gas are mixed with each other, wherein a supply of the metal compound and the reactant gas is stopped to remove an atmosphere in the processing chamber after the metal compound and the reactant gas are supplied simultaneously to the processing chamber so that the metal compound and the reactant gas are mixed with each other, after which the reactant gas is supplied to the processing chamber and an atmosphere in the processing chamber is subsequently removed by stopping a supply of the reactant gas.

3. A method of manufacturing a semiconductor device comprising:
forming a first metal film on a substrate placed in a processing chamber by alternately supplying a metal compound that is an inorganic raw material and a reactant gas that has reactivity to the metal compound to the processing chamber more than once; and
forming a second metal film on the substrate by supplying at least one type of a metal compound that is an inorganic raw material and a reactant gas that has reactivity to the metal compound to the processing chamber so that the metal compound and the reactant gas are mixed with each other, wherein, the first metal film is a laminated film of a third metal film and a fourth metal film formed by carrying out, a predetermined number of times, a process by which the third metal film is formed on the substrate by alternately supplying a first metal compound and the reactant gas to the processing chamber more than once and a process by which the fourth metal film is formed on the substrate by alternately supplying a second metal compound that is different from the first metal compound and the reactant gas to the processing chamber more than once.

4. A method of manufacturing a semiconductor device comprising:
forming a first metal film on a substrate placed in a processing chamber by alternately supplying at least one type of a metal compound that is an inorganic raw material and a reactant gas that has reactivity to the metal compound to the processing chamber more than once; and
forming a second metal film by simultaneously supplying at least one type of a metal compound that is an inorganic raw material and a reactant gas that has reactivity to the metal compound to the processing chamber once so that the metal compound and the reactant gas are mixed with each other.

5. A substrate processing apparatus comprising:
a processing chamber that accommodates a substrate;
a metal compound supply system that supplies at least one type of a metal compound that is an inorganic raw material to the processing chamber;
a reactant gas supply system that supplies a reactant gas that has reactivity to the metal compound to the processing chamber;
an exhaust system that exhausts an atmosphere in the processing chamber; and
a control portion that controls the metal compound supply system, the reactant gas supply system, and the exhaust system,
wherein the control portion carries out an alternate supply process by which a first metal film is formed on the substrate by alternately supplying the metal compound and the reactant gas to the processing chamber more than once and a simultaneous supply process by which a second metal film is formed on the substrate by simultaneously supplying the metal compound and the reactant gas to the processing chamber once so that the metal compound and the reactant gas are mixed with each other by controlling the metal compound supply system, the reactant gas supply system, and the exhaust system, so that a predetermined metal film is formed on the substrate.
